(19) United States
(12) Patent Application Publication
(10) Pub. No.: US 2017/0005295 A1
(43) Pub. Date: Jan. 5, 2017

(54) LIGHT EXTRACTION LAYERED BODY, ORGANIC ELECTROLUMINESCENCE ELEMENT, AND METHOD FOR MANUFACTURING SAME

(71) Applicant: KONICA MINOLTA, INC., Tokyo (JP)

(72) Inventors: Akihiko TAKEDA, Sagamihara-shi (JP); Takaaki KUROKI, Hachioji-shi (JP)

(21) Appl. No.: 15/125,849

(22) PCT Filed: Apr. 3, 2015
(86) PCT No.: PCT/JP2015/060548

§ 371 Date: Sep. 13, 2016

(30) Foreign Application Priority Data
Apr. 28, 2014 (JP) 2014-093198

(51) Int. Cl. H01L 51/52; H01L 51/56; H01L 51/00

(52) U.S. Cl. CPC H01L 51/5268; H01L 51/0031; H01L 51/524; H01L 51/5206; H01L 51/56; H01L 51/0043; H01L 51/004; H01L 2251/5338; H01L 2251/558

(57) ABSTRACT

A light extraction layered body, characterized in being flexible enough to exhibit no cracking when a flex test is performed by inducing ten cycles of bending at a flex radius of 5 mm and a bend angle of 180° in a layered body in which a light extraction layer is provided on one main surface of a transparent substrate that measures 3 μm to 50 μm in thickness, and when subsequently a 500×500 μm surface region is observed in the light extraction layer using a light diffraction microscope.

### TECHNICAL FIELD

The present invention relates to a light extraction layered body, an organic electroluminescence element, and a method for manufacturing thereof, and relates to an organic electroluminescence element whose element life is improved without impairment of the light extraction efficiency even bending at an extremely small radius of curvature.

### BACKGROUND ART

An organic electroluminescence element (hereinafter, also referred to as “organic EL element”) that utilizes electroluminescence (Electro Luminescence, hereinafter referred to as “EL” shortly) of an organic material can emit light at a low voltage of approximately several volts to several ten volts, is a thin-film-type completely-solid state element, and has many excellent advantages such as high luminance, high light emission efficiency, small thickness and light weight.

Accordingly, the element is being attracted attention, as surface emitting bodies which are used as backlights for various kinds of displays, display boards such as signboards and emergency lights, various lighting sources, and the like. Furthermore, since the organic EL element has a small thickness, it is being attracted as a surface emitting body having flexibility.

On the other hand, in the organic EL element, since a light loss within the element is large, there is a problem that the utilization efficiency of light is approximately 20%.

As techniques of suppressing the loss of light in the element and extracting more large amount of light, there has been disclosed a configuration of providing the organic EL element on a flexible film and of having a light extraction structure at a position where the light is emitted (outermost layer) rather than the substrate (for example, Patent Literature 1).

### CITATION LIST

### Patent Literature

PTL 1: Japanese Patent Laid-Open No. 2012-84307

### SUMMARY OF INVENTION

### Technical Problem

However, in the organic EL device described in Patent Literature 1, since the device is constituted by using a resin substrate having a thickness of 100 μm, the flexibility of the substrate itself is low, and it is difficult to mount (apply) the organic EL element on (to), for example, a small mobile device. Accordingly, in a case of mounting the organic EL element on such a small mobile device, it is desired that a device is constituted by a substrate capable of bending even at an extremely small radius of curvature.

On the other hand, when a substrate having a thickness of 50 μm or less is used, although flexibility of the substrate itself with respect to such a bending can be sufficiently obtained, fine cracks are generated in each functional layer constituting the organic EL element. Among them, there is a high probability that the light extraction layer having the largest thickness among the respective functional layers may generate fine cracks, when being is bent. As a result, the light extraction efficiency of the light extraction layer is lowered, and oxygen, water, and the like penetrate into the element to thereby degrade each functional layer, resulting in making the element life short.

Therefore, the objects of the present invention are to provide a light extraction layered body without impairing the light extraction efficiency even bending at an extremely small radius of curvature, an organic electroluminescence element whose element life is improved through the use of the layered body, and a method for manufacturing the organic electroluminescence element.

### Solution to Problem

In order to accomplish the objects, the light extraction layered body of the present invention has a bending property of generating no crack when a surface region of 500 μm×500 μm of the light extraction layer is observed with a light diffraction microscope, after a bending test is performed on the layered body which is provided on one main surface of a transparent substrate having a thickness of 3 μm or more and 50 μm or less under conditions of a radius of curvature of 5 mm, a bending angle of 180 degrees, and bending cycles of ten.

Furthermore, the organic electroluminescence element of the present invention has a bending property of generating no brightness unevenness when the brightness unevenness is measured at a time of light emission of 1000 cd/m² with a 50 magnification microscope, after a bending test is performed on an organic electroluminescence element obtained by laminating at least a transparent electrode, a light-emitting functional layer, a counter electrode, and a sealing member on a layered body in which a light extraction layer is provided on one main surface of a transparent substrate having a thickness of 3 μm or more and 50 μm or less under conditions of a radius of curvature of 5 mm, a bending angle of 180 degrees, and bending cycles of ten.

The light extraction layered body and the organic electroluminescence element having such a configuration can be bent at an extremely small radius of curvature by having the transparent substrate having a thickness of 3 μm or more and 50 μm or less. Furthermore, the light extraction layered body has a characteristic bending property of generating no crack when a surface region of 500 μm×500 μm of the light extraction layer is observed with a light diffraction microscope, after a bending test is performed on the layered body under conditions of a radius of curvature of 5 mm, a bending angle of 180 degrees, and bending cycles of ten. Accordingly, it becomes possible to deform each of other functional layers constituting the organic EL element by following the bending property of the above layered body. Moreover, the organic electroluminescence element has a bending property of generating no brightness unevenness when the brightness unevenness is measured at a time of light emission of 1000 cd/m² with a 50 magnification microscope, after the same bending test is performed. Thereby, the improvement of an element life is achieved without impairing the light extraction efficiency even by bending at an extremely small radius of curvature.

### Advantageous Effects of Invention

As explained above, according to the present invention, it is possible to provide a light extraction layered body not impairing light extraction efficiency even bending at an extremely small radius of curvature, and an organic EL element whose element life is improved and a method for manufacturing the element.

### BRIEF DESCRIPTION OF DRAWINGS

FIG. 1 is a schematic cross-sectional view showing a configuration of a light extraction layered body and an organic EL element according to a first embodiment of the present invention.

FIG. 2 is a view showing the bending test according to the first embodiment of the present invention.

FIG. 3 is a schematic cross-sectional view showing the configuration of the organic EL element according to a second embodiment of the present invention.

FIG. 4 is a schematic plane view showing a scattering layer of the organic EL element according to the second embodiment of the present invention.

### DESCRIPTION OF EMBODIMENTS

Hereinafter, the embodiments of the present invention are explained by referring the drawings in the following order.

1. First embodiment: Organic EL element provided with the light extraction layer that has: the scattering layer; and the smoothing layer which contains a resin material having an elongation percentage of 10% or more in a tensile test and an inorganic material.
2. Second embodiment: Organic EL element provided with the light extraction layer that has: the scattering layer of a sea-island structure; and a smoothing layer.
3. Third embodiment: Method of manufacturing organic EL element

Note that, in the present invention, the range represented by “to” is used in a sense of including the former and latter numerals as the lower limit value and the upper limit value.

### 1. First Embodiment

### Organic EL Element

(Configuration Provided with Light Extraction Layer Having Scattering Layer and Smoothing Layer of Urethane-Based Material)

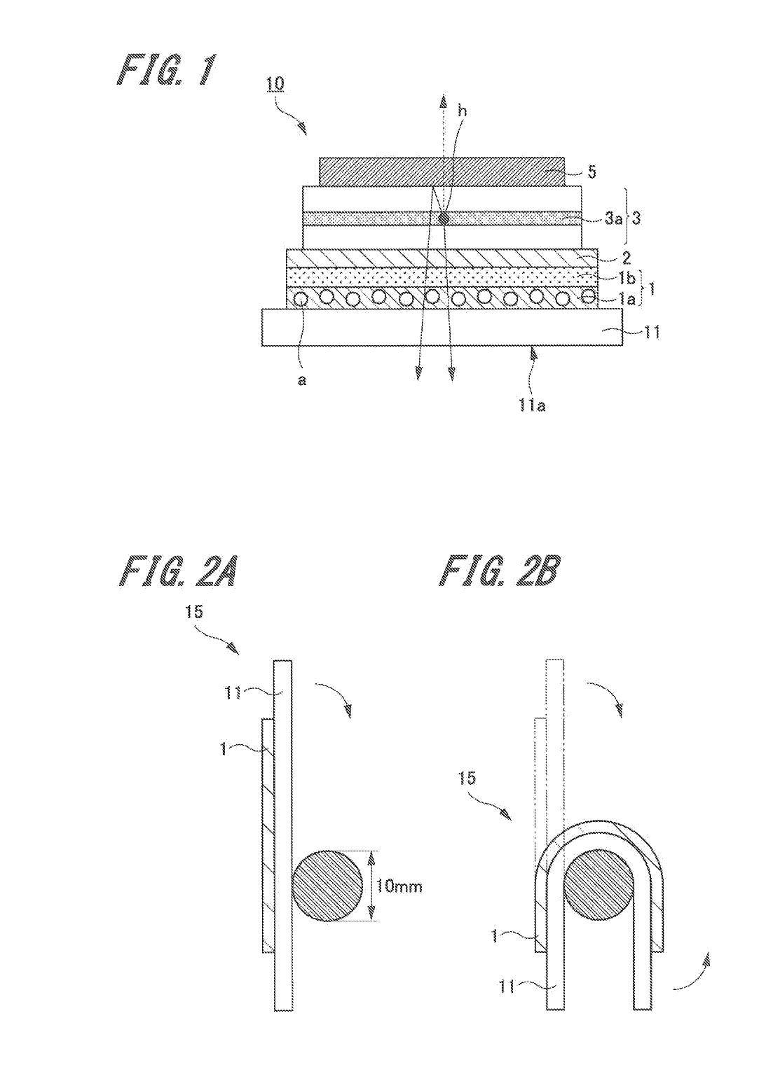

FIG. 1 is a schematic cross-sectional view showing the configuration of the organic EL element according to the first embodiment of the present invention. In the organic EL element 10 shown in the figure, a light extraction layer 1, a transparent electrode 2, a light-emitting functional layer 3, and a counter electrode 5 are provided, in this order, on one main surface (internal extraction side) of a transparent substrate 11. Furthermore, the light extraction layer 1 has a configuration in which a scattering layer 1a and a smoothing layer 1b are provided in this order from the transparent substrate 11 side.

Note that, in the present embodiment, it is characteristic that the smoothing layer 1b is configured by containing a resin material having an elongation percentage of 10% or more in a tensile test and an inorganic material.

Furthermore, the organic EL element 10 has a configuration in which the light extraction layer 1 is sandwiched between the transparent substrate 11 and the transparent electrode 2, and may be provided with, for example, other layer between the transparent substrate 11 and the transparent electrode 2.

Moreover, not shown in the figure, the organic EL element 10 has a configuration in which a sealing member that seals the light-emitting functional layer 3 is provided on the main surface side of the transparent substrate 11, and a protection member may also be provided.

Hereinafter, with respect to each portion constituting the organic EL element 10 of the present invention, explanation will be done in the order of the transparent substrate 11, the light extraction layer 1, the transparent electrode 2, the counter electrode 5, the light-emitting functional layer 3, and the sealing member.

<Transparent substrate 11>

The transparent substrate 11 to be applied to the organic EL element of the present invention is a flexible resin substrate which can be bent and has flexibility, and is a transparent substrate of a thin film having a thickness within the range of 3 to 50 μm.

A material of the transparent substrate 11 according to the present invention is not particularly limited if each structural layer described below can be held.

Examples of the resin materials include polyesters such as polyethylene terephthalate (abbreviation: PET) and polyethylene naphthalate (abbreviation: PEN), polyethylene, polypropylene, cellulose esters or derivative thereof such as cellophane, cellulose diacetate, cellulose triacetate (abbreviation: TAC), cellulose acetate butylate, cellulose acetate propionate (abbreviation: CAP), cellulose acetate phthalate and cellulose nitrate, polyvinylidene chloride, polyvinyl alcohol, polyethylene vinyl alcohol, syndiotactic polystyrene, polycarbonate (abbreviation: PC), norbornen resin, polymethylpenten, polyether ketone, polyimide, polyether sulphone (abbreviation: PES), polyphenylene sulfide, polysulphones, polyether imide, polyether ketone imide, polyamide, fluoro resin, Nylon, polymethyl methacrylate, acryl or polyallylates, cycloolefins-based resins such as Alton (commercial name, manufactured by JSR) or APEL (commercial name, manufactured by Mitsui Chemicals), and the like.

Among these resin materials, a film such as polyethylene terephthalate (abbreviation: PET), polybutylene terephthalate, polyethylene naphthalate (abbreviation: PEN), or polycarbonate (abbreviation: PC) is preferably used as the flexible transparent substrate 11, from the viewpoints of cost and availability. In addition, these resin materials may be un-stretched films or stretched films.

Moreover, a film made of inorganic materials or organic materials, or a hybrid film made by combining these films may be formed on the surface of the resin material. The film or the hybrid film is preferably a barrier film (barrier membrane) having a water transmission rate (25±0.5° C., relative humidity (90±2%) RH) measured in accordance with the method of JIS-K-7129-1992 of 0.01 g/(m²·0.24 h) or less. Furthermore, the film is preferably a high barrier film having an oxygen transmission rate measured in accordance with the method of JIS-K-7126-1987 of 10⁻³ ml/(m²·24 h·atm) or less and a water vapor transmission rate of 10⁻⁵ g/(m²·24 h) or less.

A material that forms the barrier film may be a material having a function of suppressing intrusion of substances which deteriorate the element, such as water vapor and oxygen. For example, there can be used silicon oxide, silicon dioxide, silicon nitride, and the like. Furthermore, in order to improve fragility of inorganic films composed of these materials, it is more preferably to form a laminated structure of the inorganic layer composed of these materials and an organic layer. The lamination order of the inorganic layer and the organic layer is not particularly limited, and it is preferable to alternately laminate both of the layers plural times.

The method of forming the barrier film is not particularly limited, and there can be used, for example, vacuum vapor deposition method, spattering method, reactive spattering method, molecular beam epitaxial method, cluster-ion beam method, ion plating method, plasma polymerization method, atmospheric pressure plasma polymerization method, plasma CVD method, laser CVD method, thermal CVD method, coating method, and the like. Particularly preferable is the atmospheric pressure plasma polymerization method described in Japanese Patent Application Laid-Open No. 2004-68143.

A thickness of the transparent substrate 11 according to the present invention is within the range of 3 to 50 μm, more preferably within the range of 3 to 30 μm. In addition, in a case where the above-described barrier film is formed, the total film thickness is within the above range. When the film thickness is 3 μm or more, a uniform substrate having flatness can be formed and thus, when each functional layer is formed on the transparent substrate 11, a uniform layer can be formed without positional displacement and wrinkles. Furthermore, when the film thickness is 50 μm or less, it is possible to impart a flexibility of a radius of curvature of 5 mm or less.

Note that the thickness of the transparent substrate 11 is measured by using a micrometer.

[Method of Manufacturing Transparent Substrate]

The transparent substrate 11 applicable to the present invention can be produced by an ordinary well-known film forming method. For example, it is possible to produce an un-stretched transparent substrate 11 which is substantially amorphous and not oriented, by melting of resins employed as a material through the use of an extruder, extrusion through a circular die or a T die and then immediate cooling. Furthermore, it is possible to produce a stretched transparent substrate 11 by stretching the un-stretched transparent substrate 11 in the transparent substrate 11 transporting direction (longitudinal direction: MD direction) or perpendicular to the transparent substrate 11 transporting direction (lateral direction: TD direction) according to a conventional method such as uniaxial stretching, tenter system sequential biaxial stretching, tenter system simultaneous biaxial stretching, or tubular system simultaneous biaxial stretching. In this case, it is possible to appropriately select a draw ratio in accordance with resins serving as the raw material for the transparent substrate 11, and the ratio is preferably within the range of 2 to 10 times in the longitudinal direction and in the lateral direction.

Note that, in a case where the transparent substrate 11 has the barrier layer, the barrier layer is formed on the thus manufactured un-stretched or stretched transparent substrate 11.

(Application of Support Film)

In the present invention, from the viewpoint that a thin film transparent substrate 11 having a thickness within the range of 3 to 50 μm is used, the transparent substrate 11 is easily deformed or broken during the manufacturing process, and thus it is difficult to handle the transparent substrate 11. Furthermore, when each functional layer constituting the organic EL element 10 is formed on the transparent substrate 11, it is important to maintain a high flatness at a certain position, and thus it becomes necessary to apply tension form both sides of the transparent substrate 11. However, since the thickness of the transparent substrate 11 is thin and the transparent substrate 11 has insufficient rigidity, positional displacement and wrinkles are generated, and thus it becomes difficult to accurately and uniformly form a layer.

Therefore, from the viewpoint of preventing the above problem, it is preferable to apply a support film. The role of the support film is for the temporary use only at the time of manufacturing of the flexible organic EL element, and, after each predetermined functional layer is laminated on the transparent substrate 11, the support film is peeled off from the transparent substrate 11.

Examples of the resin materials, each of which can be applied to the support film can include the above-described various resin materials used for the transparent substrate 11.

A thickness of the support film is not particularly limited, and is preferably 50 to 300 μm in consideration of mechanical strength, handling property, and the like. Note that the thickness of the support film can be measured by using a micrometer.

The method of imparting the support film to the transparent substrate 11 according to the present invention can include a method for forming an adhesive layer between the transparent substrate 11 and the support film, and then pressing them by a nip roller or the like to thereby closely adhere them to each other, or a method for closely adhering them to each other, after laminating the transparent substrate 11 and the support film, by providing a potential difference between both of the films laminated under vacuum to thereby electrically charge them. The method for closely adhering them by electrically charging is a method for closely adhering both of the films electrostatically by filling both of the films with reverse charge to each other, and after the organic EL element 10 is manufactured, both of the films are peeled off by removal of the charge in the discharging process.

<Light Extraction Layer 1>

### 1. Configuration and Properties

The light extraction layer 1 is sandwiched between the transparent substrate 11 and the transparent electrode 2, and has a configuration of providing the scattering layer 1a and the smoothing layer 1b in this order from the transparent substrate 11 side. In addition, it is characteristic that the smoothing layer 1b contains a resin material having an elongation percentage of 10% or more in a tensile test and an inorganic material.

A refractive index of the light extraction layer 1 at a wavelength of 550 nm is preferably within the range of 1.7 or more and less than 2.5.

The waveguide mode light which is trapped in the light-emitting layer 3a of the organic EL element 10 and the plasmon mode light which is reflected from the counter electrode is lights of the specific optical modes, and it is necessary to have a refractive index of at least 1.7 or more in order to extract such lights. On the other hand, in the highest order mode, there is almost no light in the area of a refractive index of 2.5 or more, and even by using light having a higher refractive index of 2.5 or more, the amount of light to be extracted is not increased, and thus the refractive index may be less than 2.5.

Practically, it is preferable that each refractive index of the light scattering layer 1a and the smoothing layer 1b is in the range of 1.7 or more and less than 2.5, but since it is difficult to individually measure the refractive index of each layer, the refractive index of the light extraction layer 1 as the whole may satisfy the above range.

Note that the measurement of the refractive index is carried out by irradiation with the light beam having the shortest maximum emission wavelength in the maximum emission wavelength of the emitted light h from the light-emitting functional layer 3 in an atmosphere of 25° C., and measuring by using Abbe refractometer (manufactured by ATAGA Co., DR-M2).

Moreover, a haze value (a ratio of the scattering transmittance to total light transmittance) of the light extraction layer 1 is preferably 30% or more. When the haze value is 30% or more, the light emission efficiency can be improved.

Note that the haze value is a physical property value calculated by receiving (i) the influence of the difference of the refractive indexes of compositions in the layer, and (ii) the influence of the surface shape. In the present invention, the haze value of the light extraction layer 1 obtained by laminating the smoothing layer 1b on the scattering layer 1a. Namely, there can be measured the haze value obtained by eliminating the influence (ii), by measuring the haze value while suppressing a surface roughness to be less than a certain degree.

Furthermore, the light extraction layer 1 of the present invention has preferably a visual ray transmittance of preferably 50% or more, preferably 55% or more, and particularly preferably 60% or more.

It is preferable that the transmittance of the light extraction layer 1 is as high as possible, but it is assumed that the practical value is kept less than 80%. The transmittance of the light extraction layer 1 is more preferably less than 85%, particularly preferably less than 90%.

### 2. Scattering Layer 1a

### Light Extraction Layer 1

The light scattering layer 1a of the present invention is constituted by using a light scattering material which is mixture of the binder (layer medium) and the light scattering particles a, and thus, is a mixed scattering layer utilizing the difference in refractive index between the binder and the light scattering particles a.

The scattering layer 1a is formed by coating on the transparent substrate 11, drying, and curing a solution of a light scattering material (hereinafter, referred to as a coating solution of scattering layer) containing the light scattering particles a and the binder.

(2.1 Refractive Index)

The light scattering layer 1a is preferably a high refractive index layer having a refractive index within the range of 1.7 or more and less than 3.0 in an atmosphere of a temperature of 25° C. and a humidity of 55% RH.

In this case, when the scattering layer 1a is formed by mixing the binder and the light scattering particles a, the layer as a whole satisfies the refractive index of 1.7 or more and less than 3.0, and the refractive index of each element may be less than 1.7 or 3.0 or more. In a case of such a mixed system, the refractive index of the whole of the light scattering layer 1a can be substituted by a calculated refractive index which is calculated using a sum obtained by multiplying the refractive indexes being inherent to each material and the mixing ratio.

Note that, if the whole of the layer can satisfy the refractive index of 1.7 or more and less than 3.0, the scattering layer may be formed by using a single material.

The scattering layer 1a is a layer that improves the light extraction efficiency, is a layer provided between the transparent substrate 11 and the transparent electrode 2, and is particularly preferably provided at the position closest to the outermost surface of the transparent substrate 11 on the transparent substrate 11.

The scattering layer 1a is composed of the binder and the light scattering particles a contained in the binder.

The difference of the refractive index between the resin material (monomer or polymer) of the binder which will be described below and the light scattering particles a contained therein is 0.03 or more, preferably 0.1 or more preferably 0.2 or more, and particularly preferably 0.3 or more. When the refractive index difference between the binder and the light scattering particles a is 0.03 or more, the scattering effect is generated in the interface between the binder and the light scattering particles a. The larger the difference in refractive index becomes, the larger the refraction in the interface becomes, and thus the scattering effect is improved.

(2.2 Average Particle Size of Light Scattering Particles)

The scattering layer 1a is, as described above, a layer where the light is scattered by utilizing the difference of the refractive index between the binder and the light scattering particle a. Accordingly, the contained light scattering particle a is a transparent particle having a particle size of the region where the Mie scattering of the visual light is generated, or more, and the average particle size is 150 to 350 nm, preferably 150 to 250 nm.

When the upper limit of the average particle size is 250 nm, since it is possible to make the thickness of the scattering layer 1a small, and at the same time, to make the thickness of the smoothing layer 1b which smooths the surface of the scattering layer 1a small, it is advantageous also from the viewpoint of load of the processes and absorption by the layer. On the other hand, when the lower limit of the particle size is 150 nm, it is possible to reliably obtain the scattering effect of the emitted light.

Here, the average particle size of the light scattering particle a can be measured by image-processing of a photograph of transmission electron microscope (TEM sectional image).

Note that, in the light scattering particle a within the average particle size of the range of 150 to 350 nm, the smaller the average particle size is, the light having a short wavelength can easily be scattered, and the larger the average particle size is, the light having a high wavelength can easily be scattered. Accordingly, the use may be possible in the combination of the light scattering particle having a small average particle size and the light scattering particle having a large average particle size.

(2.3 Kinds of Light Scattering Particle, and the Like)

The light scattering particle a is not particularly limited and can be appropriately selected depending on the purpose, and may be an organic fine particle or an inorganic fine particle. Particularly preferable is an inorganic fine particle having a high refractive index.

Examples of the organic fine particle having a high refractive index include polymethyl methacrylate beads, acryl-styrene copolymer beads, melamine beads, polycarbonate beads, styrene beads, cross-linked polystyrene beads, polyvinyl chloride beads and benzoguanamine-melamine formaldehyde beads, and the like.

Examples of the inorganic fine particles each having a high refractive index include an inorganic oxide particle composed of at least one oxide of a metal selected from zirconium, titanium, indium, zinc, antimony, cerium, niobium tungsten, and the like. Specific examples of the inorganic oxide particle include ZrO₂, TiO₂, BaTiO₃, In₂O₃, ZnO, Sb₂O₃, ITO, CeO₂, Nb₂O₅ and WO₃, and the like, and among them, preferable is TiO₂, BaTiO₃, ZrO₂, CeO₂ and Nb₂O₅, most preferable is TiO₂. Among the TiO₂, the rutile-type is more preferable than the anatase-type, because, due to low catalytic activity, the weather resistance of the high refractive index layer and the adjacent layers is enhanced, and further because the refractive index is high.

In addition, in order to introduce these particles into the scattering layer 1a having a high refractive index, it may be selected which one is used, a surface-treated one or a not surface-treated one, from the viewpoint of enhancement of dispersibility and stability in a case of forming a dispersion described below.

When carrying out the surface treatment, examples of the specific surface treating material include a different kind inorganic oxide such as silicon oxide or zirconium oxide, a metal hydroxide such as aluminum hydroxide, an organic acid such as organosiloxane or stearic acid, and the like. These surface treating materials may be used alone or in combination of two or more. Among them, from the viewpoint of stability of dispersion, the surface treating material is preferably the different kind inorganic oxide and/or the metal hydroxide, more preferably the metal hydroxide.

When the inorganic oxide particle is surface-treated and coated with the surface treating material, a coating amount (generally, the coating amount is represented by a mass proportion of the surface treating material to be used for the surface treatment relative to the mass of the particle) is preferably within the range of 0.01 to 99% by mass. When the coating amount of the surface treating material is 0.01% by mass or more, enough effect of improvement of dispersibility and stability can be obtained by the surface treatment, and when 99% by mass or less, it is possible to inhibit the lowering of the refractive index of the scattering layer 1a which has a high refractive index.

In addition, a quantum dot described in WO 2009/014707 A1 or U.S. Pat. No. 6,608,439 can be suitably used as the other materials having a high refractive index.

A refractive index of the particle having a high refractive index is 1.7 or more, preferably 1.85 or more, particularly preferably 2.0 or more. When the refractive index is 1.7 or more, since a difference of the refractive index from the binder becomes large to increase the scattering amount, the light extraction efficiency can be improved effectively.

On the other hand, the upper limit of the refractive index of the particle having a high refractive index is less than 3.0. If the difference of the refractive index from the binder is large, a sufficient scattering amount can be obtained, and thus improvement effect of the light extraction efficiency can be obtained.

As to the arrangement of the particles having a high refractive index, the light scattering particles a are arranged so as to be in contact with or near the interface between the scattering layer 1a and the smoothing layer 1b in a thickness of the average particle size. Accordingly, when the total reflection is generated in the smoothing layer 1b, the evanescent light oozed out to the scattering layer 1a can be scattered by the particle to improve the light extraction efficiency.

The content of the high refractive index particles in the light scattering layer 1a is preferably, as a volume package ratio, within the range of 1.0 to 70%, and more preferably within the range of 5 to 50%. Accordingly, it is possible to make the coarse and dense portion of the refractive index distribution in the interface between the light scattering layer 1a and the smoothing layer 1b, and to increase the amount of light scattering and improve the light extraction efficiency.

(2.4 Types of Binder, or the Like)

A well-known resins can be used as the binder without limitation, and examples include a resin film such as acrylic acid esters, methacrylic acid esters, polyethylene terephthalate (PET), polybutylene terephthalate, polyethylene naphthalate (PEN), polycarbonate (PC), polyarylate, polyvinyl chloride (PVC), polyethylene (PE), polypropylene (PP), polystyrene (PS), nylon (Ny), aromatic polyamide, polyether ether ketone, polysulfone, polyether sulfone, polyimide, polyether imide, a heat resistive transparent film which has the silsesquioxane as a basic skeleton having an organic and inorganic hybrid structure (product name Sila-DEC, manufactured by Chisso Corporation), and a perfluoroalkyl group-containing silane compound (for example, heptadecafluoro-1,1,2,2-tetradecyl)triethoxysilan), a fluorine-containing copolymer having constituent units of a fluorine-containing monomer and a monomer for imparting a cross-linkable group, and the like. These resins may be used by mixing of two or more. Among them, the resin having an organic and inorganic hybrid structure is preferable.

Furthermore, it is also possible to use the following hydrophilic resin. Examples of the hydrophilic resins include a water-soluble resin, a water-dispersible resin, a colloidal dispersion resin or a mixture thereof. Examples of the hydrophilic resins include resins such as an acrylic-based resin, a polyester-based resin, a polyamide-based resin, a polyurethane-based resin and a fluorine-containing resin; and examples can include polymers such as polyvinyl alcohol, gelatin, polyethylene oxide, polyvinyl pyrrolidone, casein, starch, agar, carrageenan, polyacrylic acid, polymethacrylic acid, polyacrylamide, polymethacryl amide, polystyrene sulfonic acid, cellulose, hydroxyl ethyl cellulose, carboxyl methyl cellulose, hydroxyl ethyl cellulose, dextran, dextrin, pullulan or a water-soluble polyvinyl butyral; and among them, polyvinyl alcohol is preferred.

The resin to be used as the binder may be used alone, or in combination of two or more as necessary.

Furthermore, a known resin particle (emulsion), and the like may also be suitably used.

Moreover, a resin mainly curable by ultraviolet ray or electron beam, namely a mixed resin in which a thermoplastic resin and a solvent are blended in an ionizing radiation curable resin, or a thermosetting resin can be suitably used as the binder.

A polymer having a saturated hydrocarbon or polyether as a main chain is preferable as such a resin, and a polymer having a saturated hydrocarbon as a main chain is more preferable.

In addition, it is preferable that the above resin is cross-linked. For example, a resin having a saturated hydrocarbon as a main chain is preferably obtained by polymerization of ethylenically unsaturated monomers. In order to obtain a crosslinked resin, it is preferable to use a monomer having two or more ethylenically unsaturated groups.

Furthermore, it is particularly suitable for use, as the binder of the scattering layer 1a of the present embodiment, a compound that forms a metal oxide, a metal nitride or a metal oxide nitride by ultraviolet irradiation under the specified atmosphere. A compound that can be easily subjected to modification at a relatively low temperature described in Japanese Patent Application Laid-Open Publication No. 08-112879 is preferable as the compound suitable for the present invention.

Specific examples can include a polysiloxane (including polysilsesquioxane) having a Si—O—Si bond, a polysilazane having a Si—N—Si bond, and a polysiloxazane having the both Si—O—Si bond and Si—N—Si bond, and the like. These can be used by mixing two or more kinds. In addition, the use is possible by sequentially or simultaneously laminating the different compounds.

(2.5 Types of Solvent, or the Like)

It is preferable that the solvent to be used as the coating solution of scattering layer has a hydroxyl group (—OH group). The dispersibility of the light scattering particles a (high refraction particles) becomes extremely good by using the solvent having —OH group, and the adhesion and coating property with the above transparent substrate 11 becomes good. In addition, the light extraction efficiency is also improved.

Furthermore, it is possible to achieve rapid drying on the flexible transparent substrate 11, by using a solvent having a good absorption of light in infrared wavelength region in which the flexible transparent substrate 11 has low absorption. The solvent having the —OH group is preferably contained in an amount of at least 10% or more, and the solvent having the —OH group is more preferably contained in an amount of 50% or more, further more preferably in an amount of 60% or more, and particularly preferably in an amount of 70% or more.

In addition, in the present invention, it is preferable to contain at least one or more kinds of the solvent having a boiling point within the range of 120 to 250° C., and more preferable to contain at least one or more kinds of the solvent having a boiling point within the range of 150 to 200° C. Particularly preferable solvent is a solvent having a boiling point within the range of 150 to 200° C., and having the —OH group. It is preferable that a solvent having a boiling point of 150° C. or more but having no —OH group is not contained, and it is important that the content of such a solvent is suppressed to be less than 30%, more preferably less than 20%, and particularly preferably less than 10%.

Examples of the solvents containing the —OH group include water, methanol, ethanol, n-propanol, isopropanol, butanol, n-amyl alcohol, sec-amyl alcohol: CH₃CH₂CH₂CH(OH)CH₃, 3-pen ethanol: CH₃CH₂CH(OH)CH₂CH₃, 2-methyl-1-butanol: CH₃CH₂CH(CH₃)CH₂OH, 3-methyl-1-butanol (isoamyl alcohol): CH₃CH(CH₃)CH₂CH₂OH, 2-methyl-2-butanol (tert-amyl alcohol): CH₃CH₂C(CH₃)₂OH, 3-methyl-2-butanol: CH₃CH(CH₃)CH(OH)CH₃ and 2,2-dimethyl-1-propanol, and the like; and can also include polyhydric alcohol derivatives such as ethylene glycol monomethyl ether (Mechisero), ethylene glycol monoethyl ether (Echisero), ethylene glycol monobutyl ether (Buchisero), propylene glycol monomethyl ether, propylene glycol monoethyl ether or propylene glycol monobutyl ether, and the like.

Furthermore, there can also be used, as the solvents, ethylene glycol monoisopropyl ether, ethylene glycol dimethyl ether, ethylene glycol diethyl ether, ethylene glycol monomethoxymethyl ether, diethylene glycol, diethylene glycol monomethyl ether, diethylene glycol monoethyl ether, diethylene glycol monobutyl ether, triethylene glycol, triethylene glycol monomethyl ether, triethylene glycol monoethyl ether, triethylene glycol monobutyl ether, tetraethylene glycol, tetraethylene glycol monobutyl ether, propylene glycol, propylene glycol monomethyl ether, propylene glycol monoethyl ether, propylene glycol monopropyl ether, propylene glycol monobutyl ether, propylene glycol monomethyl ether acetate, dipropylene glycol, dipropylene glycol monomethyl ether, dipropylene glycol monoethyl ether, dipropylene glycol monopropyl ether, dipropylene glycol monobutyl ether, dipropylene glycol monomethyl ether acetate, tripropylene glycol, tripropylene glycol monomethyl ether, tripropylene glycol monoethyl ether, tripropylene glycol monobutyl ether, 1,3-propanediol, 2-methyl-1,3-propanediol, 2,2-dimethyl-1,3-propanediol, 2-amino-2-methyl-1,3-propanediol, 1,4-butanediol, 1,3-butanediol, 1,2-butanediol, 2,3-butanediol, 3-methyl-1,3-butanediol, 1,2-pentanediol, 1,5-pentanediol, 2-methyl-2,4-pentanediol, 3-methyl-1,5-pentanediol, 1,2-hexanediol, 1,6-hexanediol, 2-ethyl-1,3-hexanediol, 2,5-dimethyl-2,5-hexanediol, polypropylene glycol monomethyl ether, glycerin, monoacetin, trimethylolethane, trimethylolpropane and 2-phenoxyethanol.

Furthermore, there can also be used, as the solvents, 1-butanol, 2-butanol, isobutanol, t-butanol, 3-methoxy-1-butanol, 3-methyl-3-methoxy butanol, 1-pentanol, 1-octanol, 2-octanol, n-nonyl alcohol, tridecyl alcohol, n-undecyl alcohol, stearyl alcohol, oleyl alcohol, benzyl alcohol, 4-hydroxy-2-butanone, diacetone alcohol, monoethanolamine, 2-aminoethanol, N-methylethanolamine, dimethylethanolamine, diethylethanolamine, N-n-butyl-ethanolamine, 2-dibutyl-aminoethanol, 2-diisopropylamino ethanol, N-methyl-diethanolamine, diethanolamine, 2,2′-(n-ethyl)imino diethanol, 2,2′-(n-butyl)imino diethanol, triethanolamine, 2-amino-2-methyl-1-propanol and 3-amino-1-propanol.

(2.6 Relation Between Film Thickness and Average Particle Size of Particle)

In the present invention, the film thickness of the scattering layer 1a is 150 to 500 nm, preferably 150 to 300 nm in view of the light extraction efficiency and the flexibility. Furthermore, from the viewpoint of the flexibility, the scattering layer is preferably formed as thin as possible, and for example, from the viewpoint of the light extraction efficiency, it is more preferable that the scattering layer has a thickness of around an average particle size so that the light scattering particle a is in contact with or adjacent to the interface between the scattering layer 1c and the smoothing layer 1d.

Furthermore, when assuming a film thickness of the scattering layer 1a to be T, and an average particle size of the light scattering particle a contained in the scattering layer 1a to be D, it is preferable that the value of T/D is within the range of 0.75 to 3.0, more preferably the value of T/D is within the range of 1.0 to 2.5, furthermore preferably the value of T/D is within the range of 1.25 to 2.0.

When the value of T/D is less than 0.75, it is not good because a probability that a light collides to the light scattering particle a becomes low, and when the value of T/D is more than 3.0, it is not good because the absorption by the light scattering particle a becomes large to make an absorption loss of the light large.

(2.7 Inplane Occupancy of Light Scattering Particle in Scattering Layer)

In the scattering layer 1a, an inplane occupancy of the light scattering particle a contained in the scattering layer 1a is set to 20 to 60%.

The “inplane occupancy of the light scattering particle a in the scattering layer 1a” means, when seeing through a plane view of the scattering layer 1a, an area occupancy of the light scattering particle a in the plane.

Here, since the scattering layer 1a of the present invention is formed as described above, when seeing from the thickness direction, a light scattering region where an amount of the light scattering particles a is large and a light transmitting region where an amount of the light scattering particles a is small are formed, and the regions exist in the form of mixed state like the sea-island structure in the plane direction. Therefore, the light which transmits the light scattering region among the lights which transmit the scattering layer 1a is scattered by the light scattering particles a to increase the extraction efficiency from the inclined direction. Furthermore, the light which transmits the light transmitting region among the lights which transmit the scattering layer 1a is almost not scattered to pass straightly, and can be extracted in the front direction of the organic EL element 10. Accordingly, while inhibiting the lowering of the light extracted in the front direction, the efficiency of the light extracted in the inclined direction is increased to extract the light in a high efficiency.

In the scattering layer 1a, a ratio of area of the light scattering region and the light transmitting region is so formed that the inplane occupancy of the light scattering particle a is 20 to 60%. When the inplane occupancy of the light scattering particle a is less than 20%, the light passing through the scattering layer 1a is not sufficiently scattered to extract the light in the inclined direction not enough. On the other hand, when the inplane occupancy of the light scattering particle a is more than 60%, the area of the light transmitting region is too small, and thus the amount of the light extracted in the front direction decreases larger than the amount of the light extracted in the inclined direction to decrease the total amount of light to be extracted. Accordingly, by forming the light scattering region and the light transmitting region so that the inplane occupancy of the light scattering particle a is 20 to 60%, it is possible to enhance every light extraction efficiency sufficiently.

(2.8 Surface Roughness Ra and Maximum Height Rt of Scattering Layer)

In the scattering layer 1a according to the present invention, a surface roughness Ra is set to 10 to 50 nm, and a maximum height Rt is set to 100 to 300 nm.

Here, in the present invention, the surface roughness Ra is represented by an arithmetic mean roughness, and the surface roughness Ra and the maximum height Rt are values measured by using the optical interferometer for roughness WYKO NT3300 (manufactured by Veecco) and the analysis software Vision 32 (ver.2.303), in the PSI mode under the conditions of 50 magnifications of objective lens and 1 magnification of inside (field of view 90 μm×120 μm).

When the surface roughness Ra of the scattering layer 1a is set to the above range, the light scattering particles a are not arranged uniformly in the plane, but the above light scattering region and the light transmitting region are formed.

Furthermore, when the maximum height Rt of the scattering layer 1a is set to the above range, there is no part where the light scattering particles a are coagulated to superimpose the light scattering particles a in the thickness direction.

### 3. Smoothing Layer 1b

The smoothing layer 1b is a layer configured by including a resin material and an inorganic material. Particularly, the resin material preferably has an elongation percentage of 10% or more in a tensile test. Furthermore, the inorganic material of the smoothing layer 1b is preferably formed of the inorganic particle having a refractive index of 2.0 or more.

The tensile test according to the present invention can measure an elongation percentage of a resin single film of the resin material according to JIS-7127. Note that the resin single film of the resin material is a film prepared by, for example, after forming a film having a dry film thickness of 30 to 100 μm by a solution casting method, the film is cured by irradiating an UV ray at a dose of 0.4 (J/cm²) with a high pressure mercury lamp (80 W/cm²).

The smoothing layer 1b is preferably formed by a resin material which has an elongation percentage of 10% or more in the tensile test in the state of the resin single film, more preferably 20% or more, furthermore preferably 30% or more. When the elongation in the tensile test is 10% or more, it is possible to endow the inside deformation such as bending, elongation and shrinkage of the smoothing layer 1b with degree of freedom.

The resin material is a curable resin which is polymerized and cured by irradiation of, for example, an active ray such as ultraviolet ray or electron beam, and is preferably an ultraviolet ray curable resin. Examples include an ultraviolet ray curable acrylate-based resin such as an ultraviolet ray curable urethane acrylate-based resin, an ultraviolet ray curable polyester acrylate-based resin, an ultraviolet ray curable epoxy acrylate-based resin, an ultraviolet ray curable polyol acrylate-based resin or an ultraviolet ray curable epoxy resin, and the like.

Among them, from the viewpoint of high elongation in tensile test and giving flexibility to the smoothing layer 1b, the ultraviolet ray curable resin is preferably composed of a resin polymer prepared by using at least one of the urethane acrylate or the acryl resin acrylate. Such a resin polymer is prepared by polymerizing a coating liquid containing a monomer or oligomer with a light or heat.

Note that the resin material may be other resin material which has a high elongation in the tensile test and can give flexibility to the smoothing layer 1b.

Examples of a photopolymerization initiator of the resin material include benzoin and a derivative thereof, acetophenone, benzophenone, hydroxybenzophenone, Michler's ketone, α-amyloxym ester, thioxanthone, and derivatives thereof. A photosensitizer may also be used together.

Furthermore, the smoothing layer 1b is preferably a high refractive index layer having a refractive index of 1.7 or more and less than 2.5. Even when the refractive index is 1.7 or more and less than 2.5, the smoothing layer may be made of a single material or may be made of a mixture. The sense of the refractive index when made of a mixture is the same as in the case of the above scattering layer 1a.

Furthermore, in order to make the smoothing layer 1b having a high refractive index, it is preferable that the smoothing layer 1b contains an inorganic material (inorganic fine particle), and particularly contains a metal oxide fine particle. Particularly, it is preferable to use in the form of fine particle sol in order to ensure the transparency of the smoothing layer 1b.

The lower limit of the refractive index of the metal oxide fine particle contained in the smoothing layer 1b is preferably 2.0 or more in the bulk state, particularly preferably 2.3 or more. Furthermore, the upper limit of the refractive index of the metal oxide fine particle is preferably 3.0 or less. When the refractive index of the metal oxide fine particle is 2.0 or more, the light extraction efficiency is improved preferably. When the refractive index of the metal oxide fine particle is 3.0 or less, multi-scattering in the smoothing layer 1b is decreased to improve the transparency preferably.

The lower limit of the particle size of the metal oxide fine particle (inorganic fine particle) contained in the smoothing layer 1b having a high refractive index is preferably 5 nm or more in usual, more preferably 10 nm or more, furthermore preferably 15 nm or moreover, the upper limit of the particle size of the metal oxide fine particle is preferably 70 nm or less, more preferably 60 nm or less, furthermore preferably 50 nm or less. When the particle size of the metal oxide fine particle is 5 nm or more, the aggregation of the metal oxide fine particles can be inhibited to improve the transparency preferably. In addition, if the particle size is large, the surface area becomes small, and the catalytic activity becomes lowered, which results in delay of degradation of the smoothing layer 1b and the adjacent layers, preferably. When the particle size of the metal oxide fine particle is 70 nm or less, the transparency of the smoothing layer can be improved preferably. The particle size distribution is not limited unless the effects of the present invention becomes worse, the distribution may be wide or narrow, or have a plurality of distributions.

The lower limit of the content of the metal oxide fine particle in the smoothing layer 1b is preferably 70% by mass or more preferably 80% by mass or more, furthermore preferably 85% by mass or more relative to the whole mass. Furthermore, the upper limit of the content of the metal oxide fine particle is preferably 97% by mass or less, more preferably 95% by mass or less. When the content of the metal oxide fine particle of the smoothing layer is 70% by mass or more, it is practically easy to make the refractive index of the smoothing layer 1b 1.80 or more. When the content of the metal oxide fine particle of the smoothing layer is 95% by mass or less, it is easy to coat the smoothing layer 1b, and the brittleness of the dried layer is small to improve the bending resistance, preferably.

The metal oxide fine particle contained in the smoothing layer 1b is more preferably, from the viewpoint of stability, TiO₂ (titanium dioxide sol). Moreover, in the TiO₂, particularly since the anatase-type is more preferable than rutile-type because, due to low catalytic activity, the weather resistance of the smoothing layer 1b and the adjacent layers is improved, and furthermore, because the refractive index can be increased.

Preparation method of the titanium dioxide sol used in the present invention may be referred to Japanese Patent Laid-open No. 63-17221, Japanese Patent Laid-open No. 07-819, Japanese Patent Laid-open No. 09-165218, Japanese Patent Laid-open No. 11-43327, and the like.

The particularly preferable primary particle size of the titanium dioxide fine particle is within the range of 5 to 15 nm, most preferably within the range of 6 to 10 nm.

Furthermore, it is important that the smoothing layer 1b has enough flatness to form the transparent electrode 2 well, and has the surface property in the surface roughness Ra of less than 100 nm, preferably less than 30 nm, particularly preferably less than 10 nm, most preferably less than 5 nm. Furthermore, from the light transmittance and the flexibility, as to the thickness of the smoothing layer 1b, it is preferable that the film thickness of the light extraction layer 1 which is a total thickness of the scattering layer 1a and the smoothing layer 1b is 1 μm or less.

### 4. Method of Forming Light Extraction Layer 1

(4.1 Method of Forming Scattering Layer 1a)

In the step of forming the scattering layer 1a, the following treatments (i) to (iii) are mainly carried out.

(i) Applying and patterning a coating solution of scattering layer on the transparent substrate 11.
(ii) Drying the coating solution of scattering layer which is applied and patterned on the transparent substrate 11.
(iii) Curing the dried coating solution of scattering layer.

In the treatment (i), the light scattering particles a having an average particle size of 150 to 350 nm and preferably a refractive index of 1.7 or more and less than 3.0 is dispersed in the binder solution, and the obtained coating solution of scattering layer is applied on the transparent substrate 11.

Note that, in a case where a curable material is not used in the materials of the scattering layer 1a, it is not necessary to carry out the treatment (iii). In such a case, it may be acceptable that the treatment (ii) has the role to cure the coating solution of scattering layer.

Furthermore, since the light scattering particle a is really a polydispersion particle and is difficult to arrange regularly, although there is diffraction effect in a local part, most of the light changes its direction by scattering to improve the light extraction efficiency.

In the coating and patterning treatment (i), a known printing method can be employed as the pattering method. Examples suitably include various types such as a photogravure coater method, a flexo printing method, a screen printing method, a microcontact printing method, an inkjet method, and a super inkjet method where a small amount of droplet is discharged, and preferred method is the inkjet method or the super inkjet method which does not use a printing plate.

In the drying treatment (ii), any drying method may be employed even if the solvent of the coating solution of scattering layer used for the coating and patterning can be removed, and for example, it is preferable to dry by irradiating selectively an infrared ray having a specified wavelength from a wavelength controllable infrared ray heater, or the like. Thereby the thin transparent substrate 11 can be dried without deformation, for example, by cutting the light having the specified wavelength region which is absorbed by the transparent substrate 11, and by irradiating selectively the light having a wavelength which is effective for evaporating the solvent in the coating solution of scattering layer 1a.

Although the drying condition is not particularly limited, it is preferable to select the irradiation time of the infrared ray, etc. for enhancing the uniformity of thickness distribution and the accuracy of the patterning.

Note that, when a curable material is used as the binder contained in the coating solution of scattering layer, the above curing treatment (iii) is carried out.

In the curing treatment (iii), when using the ultraviolet curable resin as the binder contained in the coating solution of scattering layer, any ultraviolet ray irradiation method may be employed if the ultraviolet ray can be irradiated to the coating solution of scattering layer after drying. For example, there may be used an ultraviolet ray emitted from an ultra-high pressure mercury lamp, a high pressure mercury lamp, a low pressure mercury lamp, a carbon arc, a xenon arc, a metal halide lamp, and as described above, preferable is an ultraviolet ray from an excimer UV lamp.

Furthermore, when using the ionizing radiation curable resin as the binder contained in the coating solution of scattering layer, the ionizing radiation curable resin can be cures by a usual method, that is, by irradiating an electron beam or an ultraviolet ray.

When curing by the electron radiation, an electron beam emitted from an electron beam accelerator such as cock Krumlov Walton type, Van de Graaff type, resonance transformer type, insulated core transformer type, linear type, Dynamitron type, or high frequency type having an energy within the range of 10 to 1000 keV, preferably within the range of 30 to 300 keV are used. Among these, the electron beam having an especially weak electron beam intensity is preferable, and particularly, the electron beam source “EB engine” manufactured by Hamamatsu Photonics KK, and the like can be preferably employed.

(4.2 Method of Forming Smoothing Layer)

In the step of forming the smoothing layer 1b also, the following treatments (iv) to (vi) are carried out as similar to the step of forming the scattering layer 1a.

(iv) Applying and patterning a coating solution of smoothing layer on the scattering layer 1a.
(v) Drying the coating solution of smoothing layer which is applied and patterned on the scattering layer 1a.
(vi) Curing the dried coating solution of smoothing layer.

In the treatment (iv), the inorganic fine particles having an average particle size of 5 to 70 nm and preferably a refractive index of 2.0 or more and less than 3.0 are dispersed in the binder solution, and the obtained coating solution of smoothing layer is applied on the scattering layer 1a.

Note that the solvent for the coating solution of smoothing layer may be used the same solvent as in the above scattering layer 1a, but is not limited, and may be used a different solvent. Furthermore, when the ultraviolet curable resin is used as the resin material for the binder of the coating solution of smoothing layer, it is preferable to cure by using an excimer UV lamp in the curing treatment (vi).

Note that, in the formation of the light extraction layer 1, the curing treatment (iii) may be omitted.

### <Transparent Electrode 2>

The transparent electrode 2 is an electrode which is provided at the side where the emitted light h generated in the light-emitting functional layer 3 is extracted. The transparent electrode 2 is composed of a material which can transmit the visual light, and is, for example, preferably a metal material (for example, silver). Furthermore, the transparent electrode 2 is used as an anode or a cathode with respect to the light-emitting functional layer 3 of the organic EL element 10, and at least the interface on the side which makes contact with the light-emitting functional layer 3 is composed of a material suitable for the anode or a cathode. Note that the “transparency” relating to the transparent electrode 2 according to the present invention means that the light transmittance at a wavelength of 550 nm is 50% or more.

<Counter Electrode 5>

The counter electrode 5 is an electrode which is provided in a state where the light-emitting functional layer 3 is sandwiched between the transparent electrode 2 and the counter electrode. With respect to the light-emitting functional layer 3 of the organic EL element 10, the counter electrode 5 is used as a cathode when the transparent electrode 2 is an anode, and the counter electrode is used as an anode when the transparent electrode 2 is a cathode. Therefore, at least the interface on the side which makes contact with the light-emitting functional layer 3 is composed of a material suitable for the anode or a cathode.

The counter electrode 5 having such a configuration may be configured, for example, a reflective electrode where the emitted light h generated in the light-emitting functional layer 3 is reflected to the light extraction surface 11a side of the transparent substrate 11. Furthermore, the counter electrode 5 may transmit a visual light, and in such a case, it is possible to extract the emitted light h also from the counter electrode 5 side.

Here, the anode and the cathode which configure the transparent electrode 2 or the counter electrode 5 are as follows.

### [Anode]

The material of the anode is composed of an electrode material with a high work function (4 eV or more, preferably 4.5 eV or more), and is preferably an electrode material such as a metal, an alloy, an electrically conductive compound, or a mixture thereof. Examples of the electrode material include a metal such as Au or Ag, an electrically conductive transparent material such as CuI, indium tin oxide (ITO), SnO₂ or ZnO. Furthermore, a material capable of forming an amorphous transparent conductive film such as IDIXO (In₂O₃—ZnO) may also be used.

The anode may be formed by a process that includes forming a thin film of any of these electrode materials by vapor deposition, sputtering, or other methods and pattering the thin film into a desired shape by photolithography. Alternatively, if high patterning accuracy is not necessary (about 100 μm or more), the electrode material may be vapor-deposited or deposited by sputtering through a mask with the desired shape to form a certain pattern.

Furthermore, in a case where a material capable of being coated such as a conductive organic compound is used as the anode, a wet film forming method such as a printing method or a coating method may also be used. In addition, the sheet resistance of the anode is preferably hundreds of Q/square or less.

A thickness of the anode is selected, depending on whether the cathode is used as a transparent electrode 2 or as a counter electrode 5, usually within the range of 10 nm to 1 μm, preferably in the range of 10 nm to 200 nm, considering the transparency or reflectance.

### [Cathode]

The cathode is made of an electrode material such as a metal (referred to as an electron injecting metal), an alloy, an electrically conductive compound, or a mixture thereof. Examples of the electrode material include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, Ag, and a rare earth metal, or the like. Among them, in view of electron injection property and durability against oxidation, preferred examples are a mixture of the electron injecting metal and a secondary metal that has a work function higher than that of the electron injecting metal and is more stable, such as a magnesium/silver mixture, a magnesium/aluminum mixture, a magnesium/indium mixture, an aluminum/aluminum oxide (Al₂O₃) mixture, a lithium/aluminum mixture, aluminum, and the like.

The cathode can be produced by forming a thin film of the electrode material by a method such as vapor deposition or sputtering. Furthermore, a sheet resistance of the cathode is preferably several hundred Q/square or less.

A thickness of the cathode is selected, depending on whether the cathode is used as a transparent electrode 2 or as a counter electrode 5, usually within the range of 10 nm to 5 μm, preferably in the range of 50 nm to 200 nm, considering the transparency or reflectance.

### [Preferred Aspect of Anode and Cathode]

Here, according to the preferred aspect, when the anode or/and cathode (hereinafter referred to as electrode) is a layer which is composed of silver as a main component, the layer is preferably formed on an base layer described below which contains an organic compound having a nitrogen atom or sulfur atom.

The layer which is composed of silver as a main component means that the content of silver in the electrode is 60% by mass or more, and the content of silver is preferably 80% by mass or more, the content of silver is more preferably 90% by mass or more, and the content of silver is particularly preferably 98% by mass or more.

Note that the electrode is a layer which is composed of silver as a main component, and specifically may be composed of silver alone, or may be composed of an alloy containing silver (Ag). The alloy containing silver (Ag) is preferably an alloy containing silver in an amount of 50% by mass or more. Examples of the alloy containing silver (Ag) include silver magnesium (AgMg), silver copper (AgCu), silver palladium (AgPd), silver palladium copper (AgPdCu), silver indium (AgIn), silver aluminum (AgAl), silver gold (AgAu), and the like.

Furthermore, although the electrode which is composed of silver as a main component has an enough conductivity without a high temperature annealing treatment after the formation (for example, heating process at 150° C. or more) by forming on the base layer described below, an annealing treatment, etc. may be carried out, as occasion demand, under a temperature condition that the resin substrate is not deformed after the film formation.

The electrode can be made thin because the electrode is made of silver as a main component on the base layer. The electrode is characterized in that the thickness is within the range of 2 to 20 nm, preferably within the range of 4 to 12 nm. When the thickness is 20 nm or less, the absorbed component and the reflection component of the electrode are controlled at a low level to maintain the light transmittance, preferably. Furthermore, when the thickness is 2 nm or more, the electric conductivity of the electrode can be ensured. Therefore, since the electrode having silver (Ag) as a main component has a light transmittance, the electrode is preferably used as the transparent electrode 2. The transparent electrode 2 of such metal material has a good bending property.

<Base Layer>

The base layer is a layer which contains an organic compound having a nitrogen atom or a sulfur atom. The base layer is preferably constituted by using an organic compound having a nitrogen atom or a sulfur atom with effective unshared electron pairs which are not involved in aromaticity.

In the present invention, when the electrode having silver as a main component is formed, the base layer containing an organic compound having a nitrogen atom or a sulfur atom is provided under the electrode. Accordingly, when the electrode is formed, the silver constituting the electrode interacts with the nitrogen atom or sulfur atom of the organic compound contained in the base layer and reduces the diffusion distance of the silver atom on the surface of the base layer. As a result, the effect of being able to suppress the aggregation of the silver can be expressed to form an electrode having a high uniformity.

In general, in the formation of the electrode which is composed of silver as a main component, the silver particle is easily isolated in an island shape by the film-growth of the island-growth type (Volmer-Weber: VW-type), and when the layer thickness is small, it is difficult to obtain electric conductivity, and thus a sheet resistance is increased. Therefore, although it is necessary to make the electrode thick to a certain degree in order to ensure the conductivity of the electrode, the light transmittance is lowered when the layer thickness is large, with the result that the electrode is inappropriate as a transparent electrode.

In order to solve the above problem, in a case where the base layer containing the organic compound having a nitrogen atom or a sulfur atom is provided under the electrode, the aggregation of the silver in the electrode is suppressed by the interaction of the silver with the nitrogen atom or sulfur atom. As a result, in the formation of the electrode which is composed of silver as a main component, the film formation is performed by the film-growth of the mono-layer growth type (Frank-van der Merwe: FM-type).

The base layer has the organic compound containing at least one kind of atom selected from nitrogen and sulfur, as a main component. The main component in the present invention means that the mass ratio of the organic compound containing at least one kind of atom selected from nitrogen and sulfur to the total mass of the base layer is 50% by mass or more, preferably 70% by mass or more.

Furthermore, the base layer can be provided optionally within the thickness range of 5 nm to 1 μm, and from the viewpoint of maintaining the uniformity of the electrode, the film thickness is preferably within the range of 10 to 500 nm.

The organic compound constituting the base layer may be used alone or in the mixture in combination of two or more kinds. In addition, other compound having no nitrogen atom and sulfur atom may be mixed within a range not inhibiting the effect of the present invention.

Furthermore, there may be used, as the organic compound, either a low molecular weight compound or a compound having polymer structure.

### 1. Low Molecular Organic Compound Having a Nitrogen Atom

The low molecular organic compound having a nitrogen atom is preferably a compound having a melting point of 80° C. or more, and a molecular weight M within the range of 150 to 1200. In addition, the low molecular organic compound having a nitrogen atom preferably has a larger interaction with silver, or the like, and for example, a nitrogen-containing heterocyclic compound or a phenyl-substituted amine compound.

In a case where a number n of the [effective unshared electron pairs] to a molecular weight M of the organic compound having a nitrogen atom is defined as an effective unshared electron pair content [n/M], the low molecular organic compound having a nitrogen atom is a compound so that the [n/M] is selected to be 2.0×10⁻³≦[n/M], more preferably within the range of 3.9×10⁻³≦[n/M].

As used herein, the term [effective unshared electron pair] refers to an unshared electron pair that is not involved in aromaticity and is not coordinated to a metal, among unshared electron pairs of a nitrogen atom contained in a compound.

As used herein, the aromaticity refers to an unsaturated ring structure in which atoms having a π electron are arranged in the form of a ring, and the aromaticity follows the so-called “Huckel's rule” which requires a condition in which the number of electrons contained in the π electron system on the ring is “4n+2” (n=0, or a natural number).

The above [effective unshared electron pair] is selected based on whether or not the unshared electron pair of a nitrogen atom is involved in the aromaticity irrespective of whether or not the nitrogen atom itself including the unshared electron pair is a hetero atom constituting the aromatic ring. For example, even when a certain nitrogen atom is a hetero atom constituting the aromatic ring, if the unshared electron pair of the nitrogen atom is not directly involved in aromaticity as an essential element, namely, if the unshared electron pair of the nitrogen atom is not directly involved in aromaticity expression as the essential element in the delocalized π electron system in the conjugated unsaturated ring structure (aromatic ring), the unshared electron pair is counted as one of the [effective unshared electron pair].

In contrast, even in a case where a certain nitrogen atom is not a hetero atom constituting an aromatic ring, if all the unshared electron pairs of the nitrogen atom are involved in the aromaticity, the unshared electron pairs of the nitrogen atom are not counted as the [effective unshared electron pair].

Note that, in a case where the unshared electron pair is used for in ion bond and a coordinate bond, the pair does not correspond to the [effective unshared electron pair]. Furthermore, when the unshared electron pair like the unshared electron pair in the nitrogen atom of nitro group is used for the resonance structure with oxygen atom, the pair exists on the nitrogen as the [effective unshared electron pair].

Note that, in respective compounds, a number n of the [effective unshared electron pair] coincides with the number of the nitrogen atoms having the [effective unshared electron pair].

Furthermore, in a case where the organic compound is constituted by using a plurality of compounds, the molecular weight M of the mixture of these compounds may be calculated on the basis of on the mixing ratio of the compounds, and the total number n of the [effective unshared electron pairs] relative to the molecular weight M is obtained as an average value of the effective unshared electron pair content [n/M], and the value is preferably in the above specified range.

Hereinafter, the following exemplary compounds No. 1 to No. 43, as compounds which satisfy the above-described effective unshared electron pair content [n/M] of 2.0×10⁻³≦[n/M], will be shown as low-molecular compounds containing nitrogen atoms constituting the base layer.

Note that, in copper phthalocyanine of the exemplary compound 31 shown below, unshared electron pairs not coordinated to the copper, among unshared electron pairs of a nitrogen atom, are counted as the [effective unshared electron pairs].

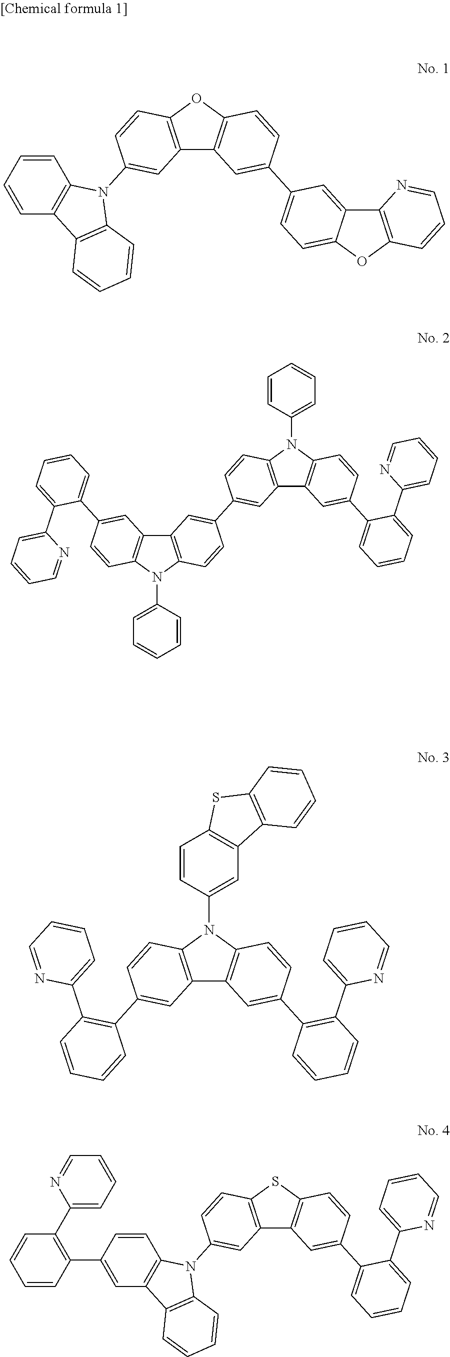 [SMILES: c1cnc2c(c1)oc1ccc(-c3ccc4oc5ccc(-n6c7ccccc7c7ccccc76)cc5c4c3)cc12 ; c1ccc(-n2c3ccc(-c4ccc5c(c4)c4cc(-c6ccccc6-c6ccccn6)ccc4n5-c4ccccc4)cc3c3cc(-c4ccccc4-c4ccccn4)ccc32)cc1 ; c1ccc(-c2ccccc2-c2ccc3c(c2)c2cc(-c4ccccc4-c4ccccn4)ccc2n3-c2ccc3sc4ccccc4c3c2)nc1 ; c1ccc(-c2ccccc2-c2ccc3sc4ccc(-n5c6ccccc6c6cc(-c7ccccc7-c7ccccn7)ccc65)cc4c3c2)nc1]

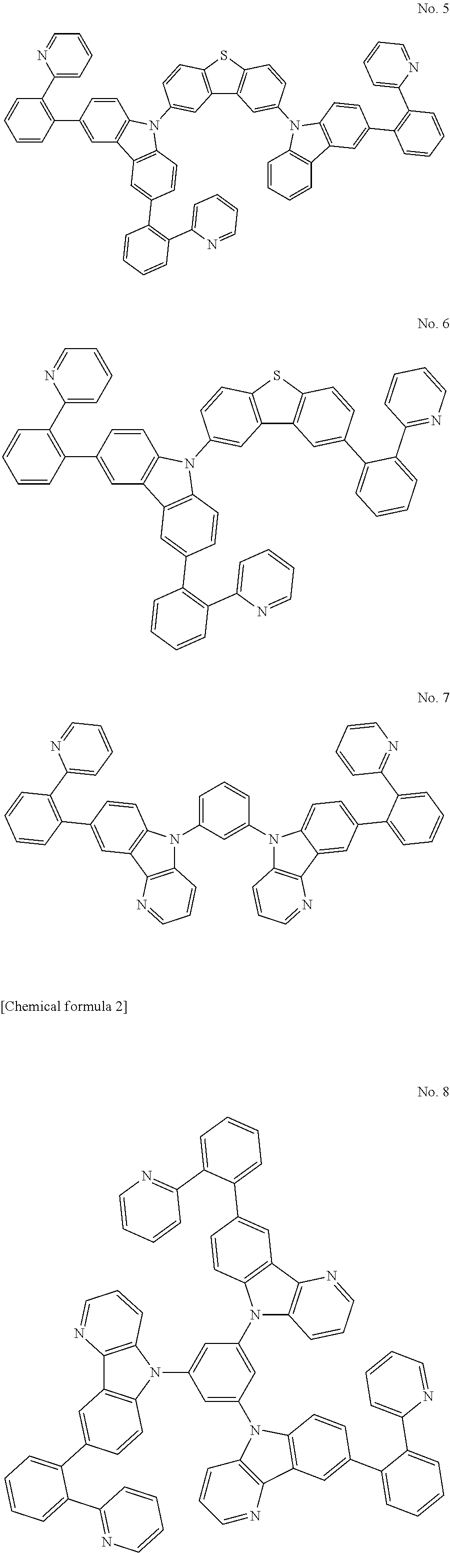 [SMILES: c1ccc(-c2ccccc2-c2ccc3c(c2)c2ccccc2n3-c2ccc3sc4ccc(-n5c6ccc(-c7ccccc7-c7ccccn7)cc6c6cc(-c7ccccc7-c7ccccn7)ccc65)cc4c3c2)nc1 ; c1ccc(-c2ccccc2-c2ccc3sc4ccc(-n5c6ccc(-c7ccccc7-c7ccccn7)cc6c6cc(-c7ccccc7-c7ccccn7)ccc65)cc4c3c2)nc1 ; c1ccc(-c2ccccc2-c2ccc3c(c2)c2ncccc2n3-c2cccc(-n3c4ccc(-c5ccccc5-c5ccccn5)cc4c4ncccc43)c2)nc1 ; c1ccc(-c2ccccc2-c2ccc3c(c2)c2ncccc2n3-c2cc(-n3c4ccc(-c5ccccc5-c5ccccn5)cc4c4ncccc43)cc(-n3c4ccc(-c5ccccc5-c5ccccn5)cc4c4ncccc43)c2)nc1]

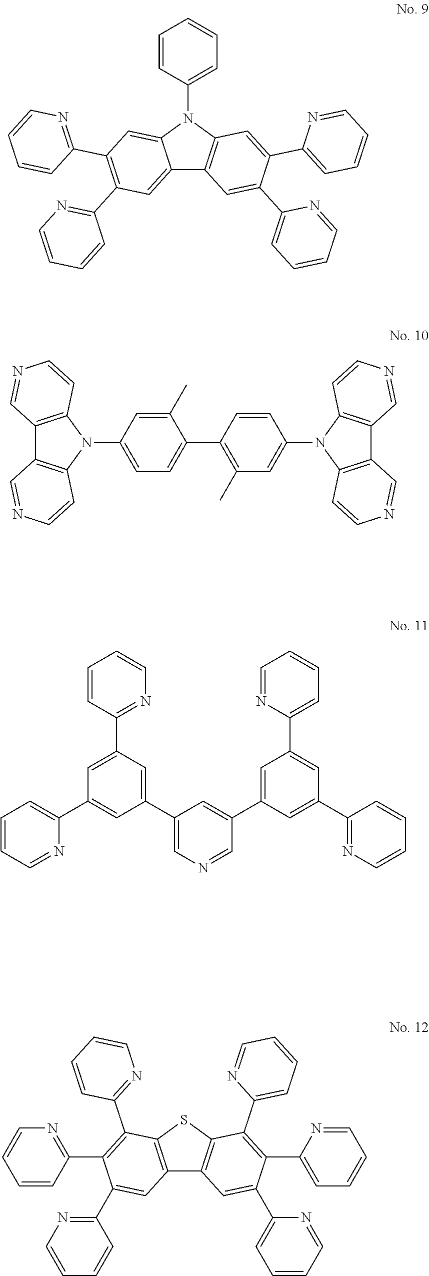 [SMILES: c1ccc(-n2c3cc(-c4ccccn4)c(-c4ccccn4)cc3c3cc(-c4ccccn4)c(-c4ccccn4)cc32)cc1 ; Cc1cc(-n2c3ccncc3c3cnccc32)ccc1-c1ccc(-n2c3ccncc3c3cnccc32)cc1C ; c1ccc(-c2cc(-c3cncc(-c4cc(-c5ccccn5)cc(-c5ccccn5)c4)c3)cc(-c3ccccn3)c2)nc1 ; c1ccc(-c2cc3c(sc4c(-c5ccccn5)c(-c5ccccn5)c(-c5ccccn5)cc43)c(-c3ccccn3)c2-c2ccccn2)nc1]

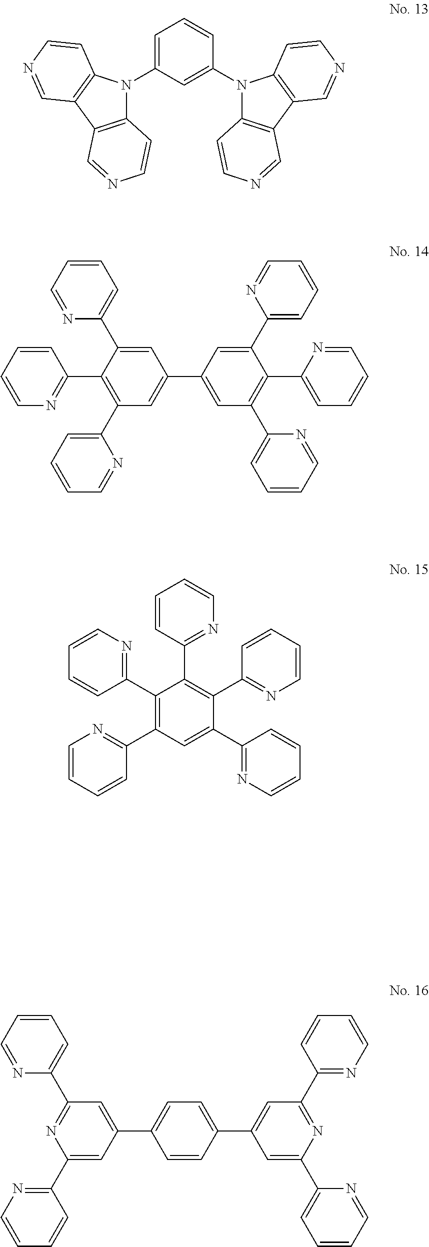 [SMILES: c1cc(-n2c3ccncc3c3cnccc32)cc(-n2c3ccncc3c3cnccc32)c1 ; c1ccc(-c2cc(-c3cc(-c4ccccn4)c(-c4ccccn4)c(-c4ccccn4)c3)cc(-c3ccccn3)c2-c2ccccn2)nc1 ; c1ccc(-c2cc(-c3ccccn3)c(-c3ccccn3)c(-c3ccccn3)c2-c2ccccn2)nc1 ; c1ccc(-c2cc(-c3ccc(-c4cc(-c5ccccn5)nc(-c5ccccn5)c4)cc3)cc(-c3ccccn3)n2)nc1]

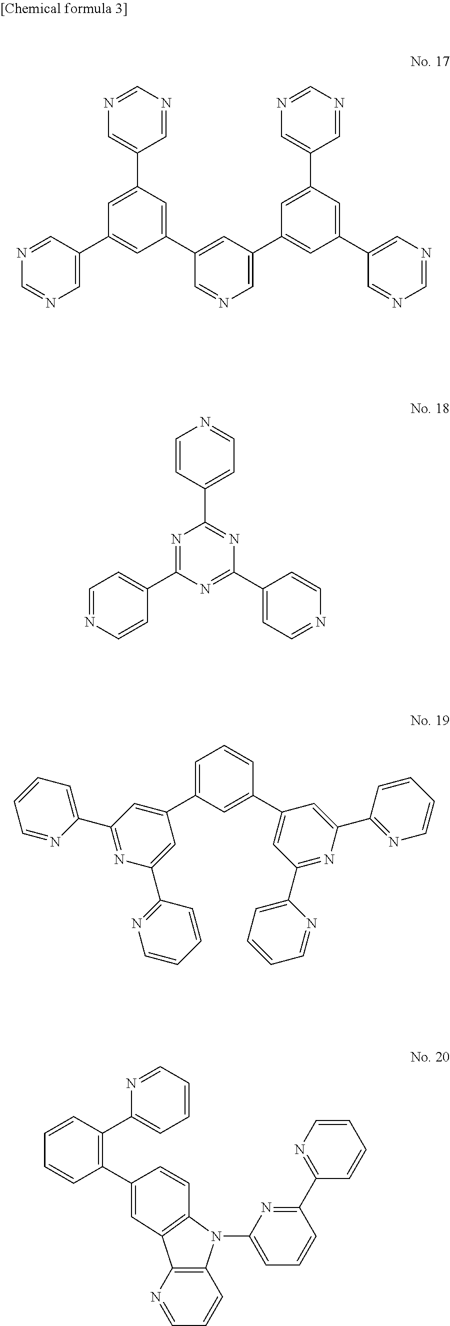 [SMILES: c1ncc(-c2cc(-c3cncnc3)cc(-c3cncc(-c4cc(-c5cncnc5)cc(-c5cncnc5)c4)c3)c2)cn1 ; c1cc(-c2nc(-c3ccncc3)nc(-c3ccncc3)n2)ccn1 ; c1ccc(-c2cc(-c3cccc(-c4cc(-c5ccccn5)nc(-c5ccccn5)c4)c3)cc(-c3ccccn3)n2)nc1 ; c1ccc(-c2cccc(-n3c4ccc(-c5ccccc5-c5ccccn5)cc4c4ncccc43)n2)nc1]

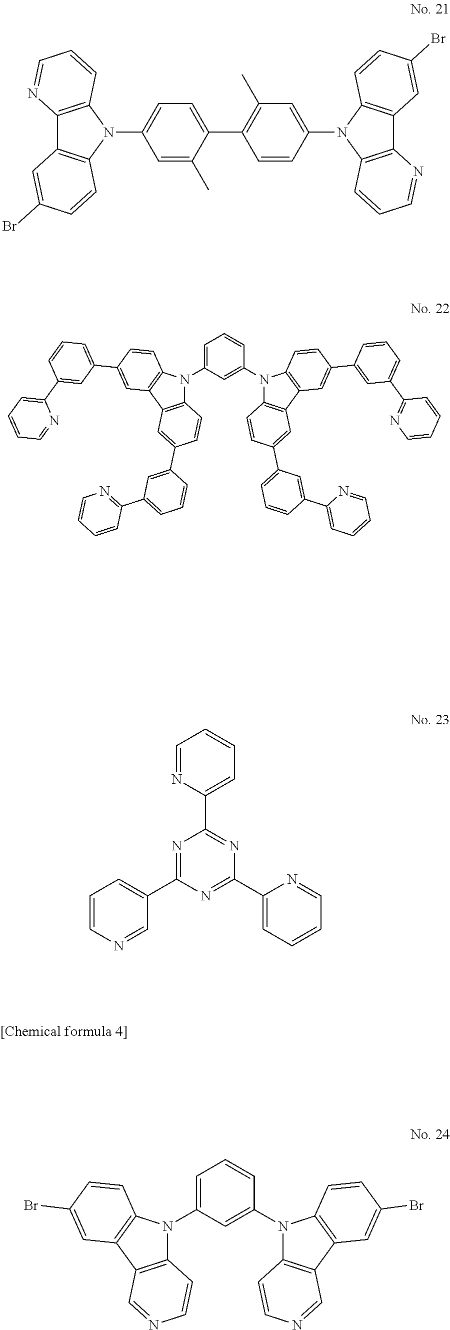 [SMILES: Cc1cc(-n2c3ccc(Br)cc3c3ncccc32)ccc1-c1ccc(-n2c3ccc(Br)cc3c3ncccc32)cc1C ; c1ccc(-c2cccc(-c3ccc4c(c3)c3cc(-c5cccc(-c6ccccn6)c5)ccc3n4-c3cccc(-n4c5ccc(-c6cccc(-c7ccccn7)c6)cc5c5cc(-c6cccc(-c7ccccn7)c6)ccc54)c3)c2)nc1 ; c1ccc(-c2nc(-c3cccnc3)nc(-c3ccccn3)n2)nc1 ; Brc1ccc2c(c1)c1cnccc1n2-c1cccc(-n2c3ccncc3c3cc(Br)ccc32)c1]

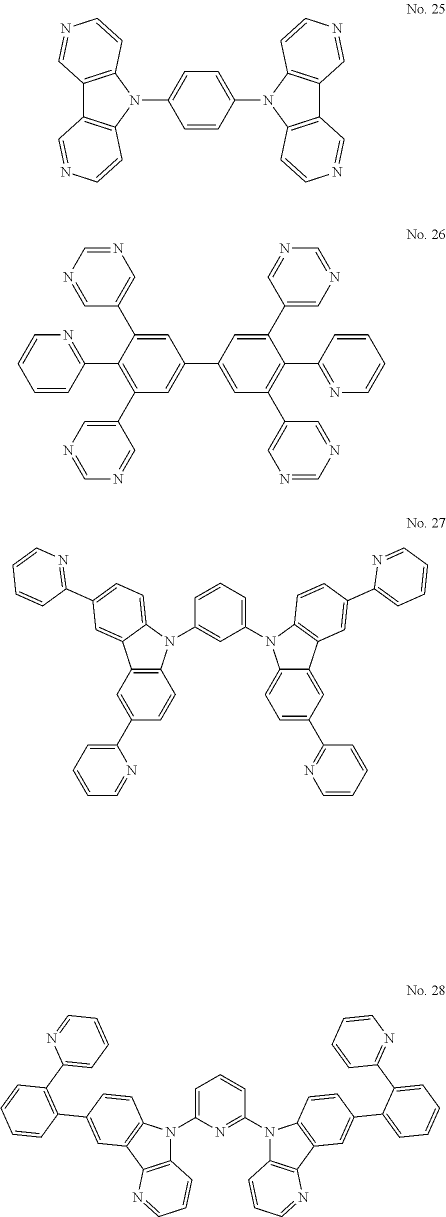 [SMILES: c1cc2c(cn1)c1cnccc1n2-c1ccc(-n2c3ccncc3c3cnccc32)cc1 ; c1ccc(-c2c(-c3cncnc3)cc(-c3cc(-c4cncnc4)c(-c4ccccn4)c(-c4cncnc4)c3)cc2-c2cncnc2)nc1 ; c1ccc(-c2ccc3c(c2)c2cc(-c4ccccn4)ccc2n3-c2cccc(-n3c4ccc(-c5ccccn5)cc4c4cc(-c5ccccn5)ccc43)c2)nc1 ; c1ccc(-c2ccccc2-c2ccc3c(c2)c2ncccc2n3-c2cccc(-n3c4ccc(-c5ccccc5-c5ccccn5)cc4c4ncccc43)n2)nc1]

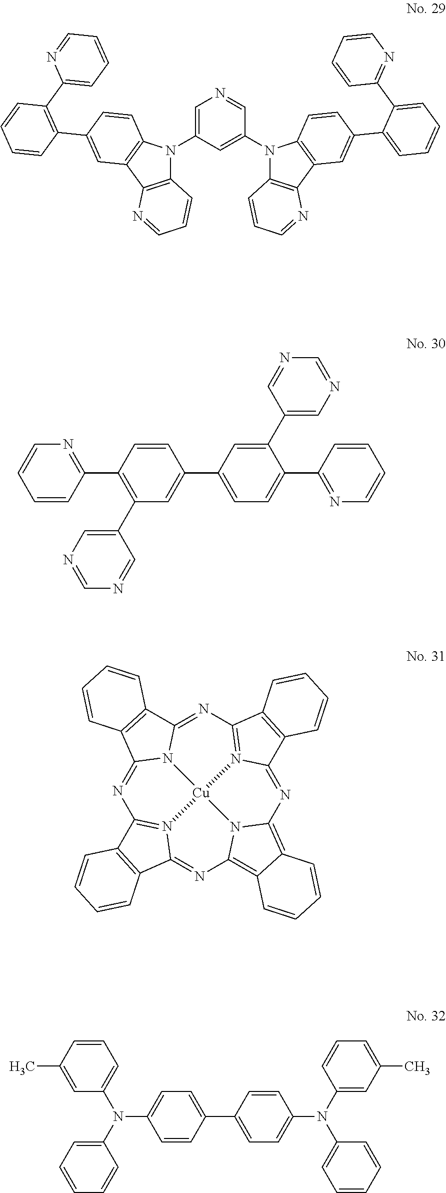

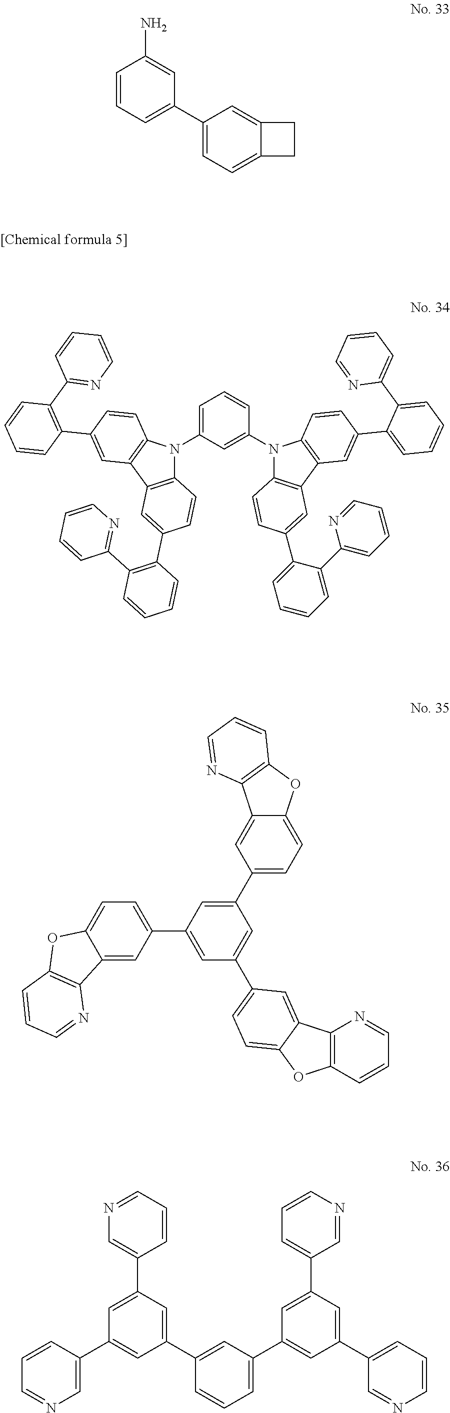 [SMILES: Nc1cccc(-c2ccc3c(c2)CC3)c1 ; c1ccc(-c2ccccc2-c2ccc3c(c2)c2cc(-c4ccccc4-c4ccccn4)ccc2n3-c2cccc(-n3c4ccc(-c5ccccc5-c5ccccn5)cc4c4cc(-c5ccccc5-c5ccccn5)ccc43)c2)nc1 ; c1cnc2c(c1)oc1ccc(-c3cc(-c4ccc5oc6cccnc6c5c4)cc(-c4ccc5oc6cccnc6c5c4)c3)cc12 ; c1cncc(-c2cc(-c3cccnc3)cc(-c3cccc(-c4cc(-c5cccnc5)cc(-c5cccnc5)c4)c3)c2)c1]

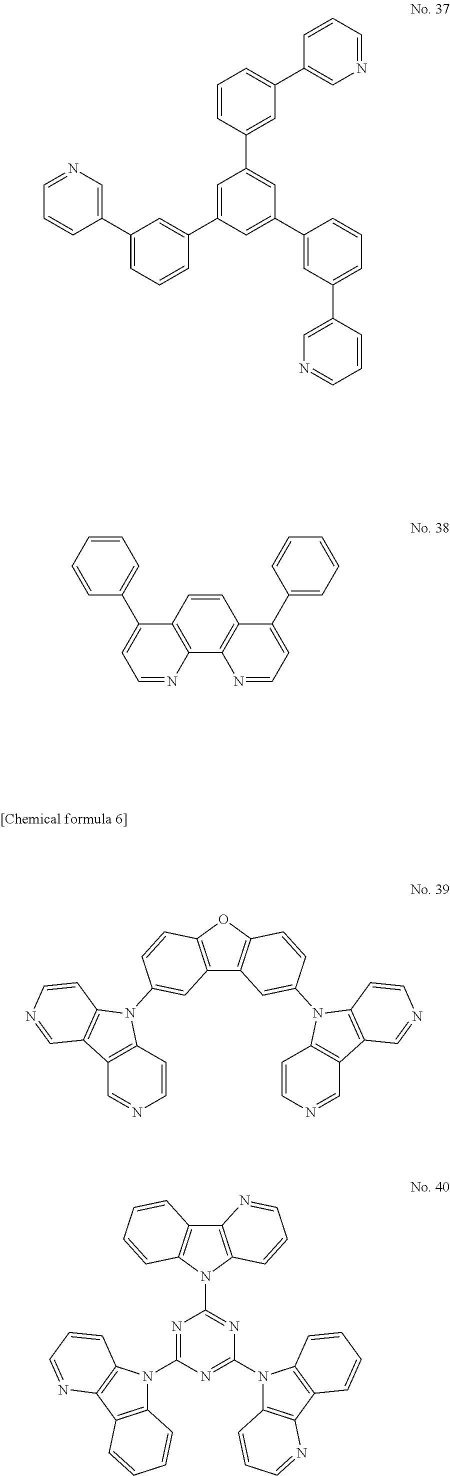 [SMILES: c1cncc(-c2cccc(-c3cc(-c4cccc(-c5cccnc5)c4)cc(-c4cccc(-c5cccnc5)c4)c3)c2)c1 ; c1ccc(-c2ccnc3c2ccc2c(-c4ccccc4)ccnc23)cc1 ; c1cc2c(cn1)c1cnccc1n2-c1ccc2oc3ccc(-n4c5ccncc5c5cnccc54)cc3c2c1 ; c1ccc2c(c1)c1ncccc1n2-c1nc(-n2c3ccccc3c3ncccc32)nc(-n2c3ccccc3c3ncccc32)n1]

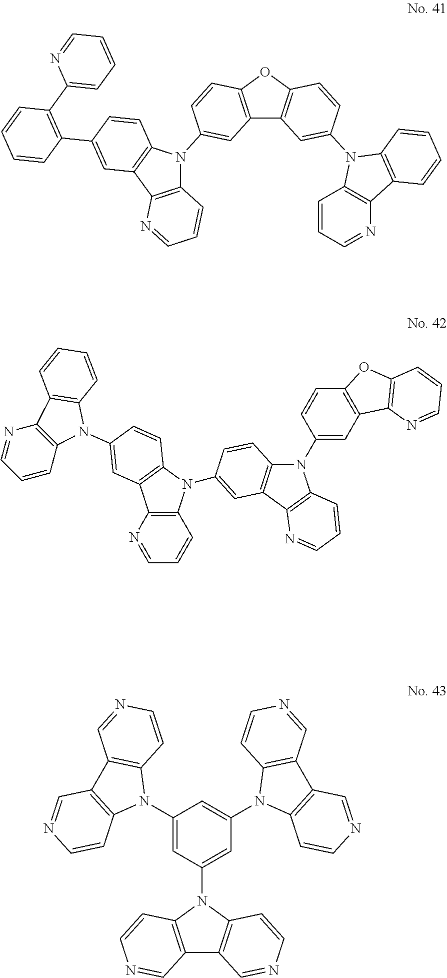 [SMILES: c1ccc(-c2ccccc2-c2ccc3c(c2)c2ncccc2n3-c2ccc3oc4ccc(-n5c6ccccc6c6ncccc65)cc4c3c2)nc1 ; c1cnc2c(c1)oc1ccc(-n3c4ccc(-n5c6ccc(-n7c8ccccc8c8ncccc87)cc6c6ncccc65)cc4c4ncccc43)cc12 ; c1cc2c(cn1)c1cnccc1n2-c1cc(-n2c3ccncc3c3cnccc32)cc(-n2c3ccncc3c3cnccc32)c1]

As to the exemplary compounds No. 1 to No. 43 described above, the number (n) of the [effective unshared electron pairs], the molecular weight (M), and the effective unshared electron pair content (n/M) are shown in the following Table 1.

TABLE 1

| Exemplary | Number [n] of | | Effective unshared |
|---|---|---|---|
| compound | the effective | Molecular | electron pair |
| number | unshared electron pairs | weight [M] | content [n/M] |
| No. 1 | 1 | 500.55 | 0.0020 |
| No. 2 | 2 | 790.95 | 0.0025 |
| No. 3 | 2 | 655.81 | 0.0030 |
| No. 4 | 2 | 655.81 | 0.0030 |
| No. 5 | 3 | 974.18 | 0.0031 |
| No. 6 | 3 | 808.99 | 0.0037 |
| No. 7 | 4 | 716.83 | 0.0056 |
| No. 8 | 6 | 1036.19 | 0.0058 |
| No. 9 | 4 | 551.64 | 0.0073 |
| No. 10 | 4 | 516.60 | 0.0077 |
| No. 11 | 5 | 539.63 | 0.0093 |
| No. 12 | 6 | 646.76 | 0.0093 |
| No. 13 | 4 | 412.45 | 0.0097 |
| No. 14 | 6 | 616.71 | 0.0097 |
| No. 15 | 5 | 463.53 | 0.0108 |
| No. 16 | 6 | 540.62 | 0.0111 |
| No. 17 | 9 | 543.58 | 0.0166 |
| No. 18 | 6 | 312.33 | 0.0192 |
| No. 19 | 6 | 540.62 | 0.0111 |
| No. 20 | 4 | 475.54 | 0.0084 |
| No. 21 | 2 | 672.41 | 0.0030 |
| No. 22 | 4 | 1021.21 | 0.0039 |
| No. 23 | 6 | 312.33 | 0.0192 |
| No. 24 | 2 | 568.26 | 0.0035 |
| No. 25 | 4 | 412.45 | 0.0097 |
| No. 26 | 10 | 620.66 | 0.0161 |
| No. 27 | 4 | 716.83 | 0.0056 |
| No. 28 | 5 | 717.82 | 0.0070 |
| No. 29 | 5 | 717.82 | 0.0070 |
| No. 30 | 6 | 464.52 | 0.0129 |
| No. 31 | 4 | 576.10 | 0.0069 |
| No. 32 | 2 | 516.67 | 0.0039 |
| No. 33 | 1 | 195.26 | 0.0051 |
| No. 34 | 4 | 1021.21 | 0.0039 |
| No. 35 | 3 | 579.60 | 0.0052 |
| No. 36 | 4 | 538.64 | 0.0074 |
| No. 37 | 3 | 537.65 | 0.0056 |
| No. 38 | 2 | 332.40 | 0.0060 |
| No. 39 | 4 | 502.15 | 0.0080 |
| No. 40 | 6 | 579.19 | 0.0104 |
| No. 41 | 3 | 653.22 | 0.0046 |
| No. 42 | 4 | 667.21 | 0.0060 |
| No. 43 | 6 | 579.19 | 0.0104 |

Other than the above exemplary compounds No. 1 to No. 43, the low molecular weight organic compounds containing a nitrogen atom can include the following compounds No. 44 to No. 47.

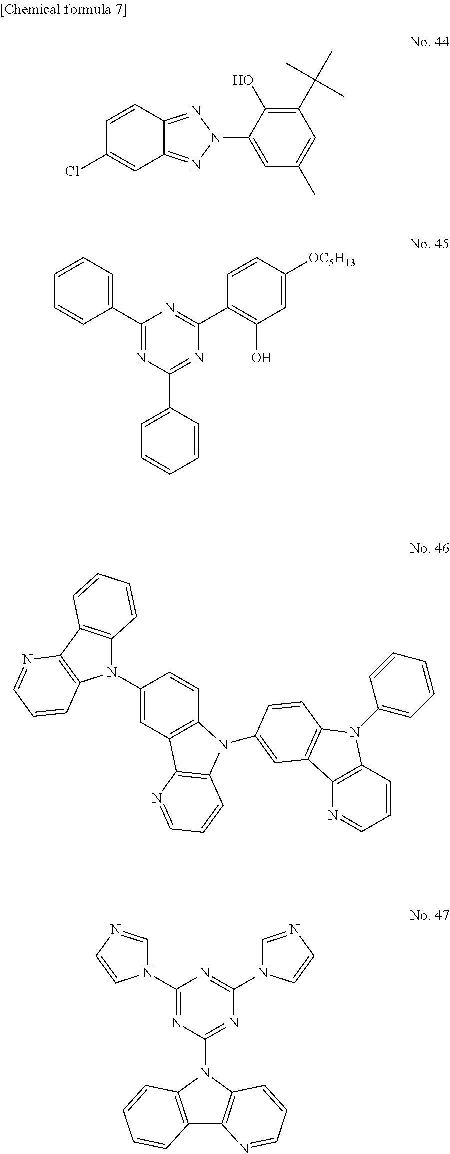

### 2. Polymer Containing a Nitrogen Atom

The polymers containing a nitrogen atom shown below as specific examples can be used as the organic compound containing a nitrogen atom which is applicable to the base layer.

The polymer containing a nitrogen atom is preferably a polymer having a weight average molecular weight within the range of 1000 to 1000000.

The polymer is not particularly limited, and is preferably a polymer having the following partial structure represented by the General formula (P1) or the following partial structure represented by the General formula (P2).

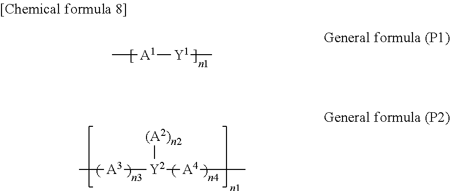

In the above General formula (P1), A¹ represents a divalent nitrogen-containing group, and Y¹ represents a divalent organic group or single bond. n1 is a number of repetition times so that the weight average molecular weight is within the range of 1000 to 1000000.

In the General formula (P2), A² represents a monovalent nitrogen-containing group. n2 represents an integer of 1 or more. n2 is preferably an integer of 1 to 3, more preferably 1 or 2 from the viewpoint of easy synthesis. When n2 is 2 or more, a plurality of A² may be the same as or different from one another. In a case where a plurality of A² is contained in the polymer having the partial structure represented by the General formula (P2), A² may be the same or different in one monomer or between monomers.

In the above General formula (P2), A³ and A⁴ represent a divalent nitrogen-containing group. A³ and A⁴ may be the same or different. Each of n3 and n4 represents independently an integer of 0 or 1.

In the above General formula (P2), Y² represents an organic group having a valence of (n2+2).

The polymer having the partial structure represented by the General formula (P1) or (P2) as the nitrogen-containing polymer may be a homopolymer composed of the single structural unit derived from the General formula (P1) or (P2), or a copolymer composed of two or more kinds of structural units derived from the General formula (P1) or (P2).

Furthermore, in addition to the structural unit shown by the General formula (P1) or (P2), other structural unit having no nitrogen-containing substituent (hereinafter referred to as “other structural unit”) may be incorporated to form a copolymer.

In the nitrogen-containing polymer, when the polymer has the other structural unit having no nitrogen atom, the content of the other structural unit is not particularly limited within the above effect can be obtained.

The content of the monomer derived from the other structural unit is within the range of 10 to 75% by mole, preferably within the range of 20 to 50% by mole relative to the monomers derived from the all structural units.

The end of the polymer having the partial structure represented by the General formula (P1) or (P2) is not particularly limited, and is suitably determined by the kind of the starting material (monomer), usual is hydrogen atom.

In the above General formula (P2), the monovalent nitrogen-containing group represented by A² is not limited unless the group is an organic group which contains nitrogen atom. Examples include amino, dithiocarbamate, thioamide, cyano (—CN), isonitrile (—N⁺≡C⁻), isocyanate (—N═C═O), thioisocyanate (—N═C═S), a group including a substituted or unsubstituted nitrogen-containing aromatic ring.

Hereinafter, specific examples of the polymers composed of the above monomer unit containing a nitrogen atom will be shown, but is not limited to the exemplary monomers in the present invention. Note that the polymer containing a nitrogen atom according to the present invention is composed of the following monomer unit in a number of repetition times such that the weight average molecular weight of the polymer is 1000 to 1000000.

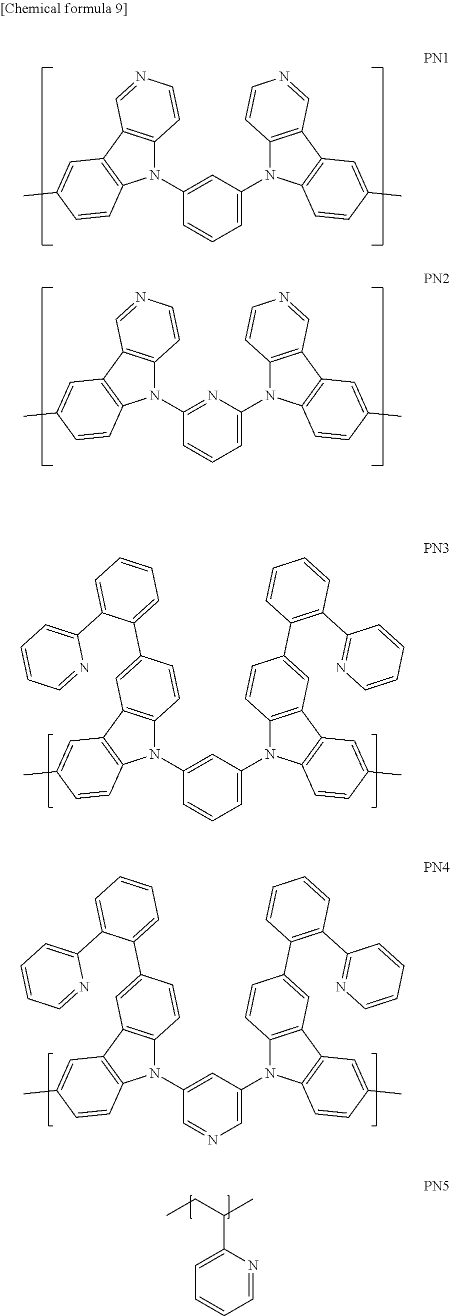

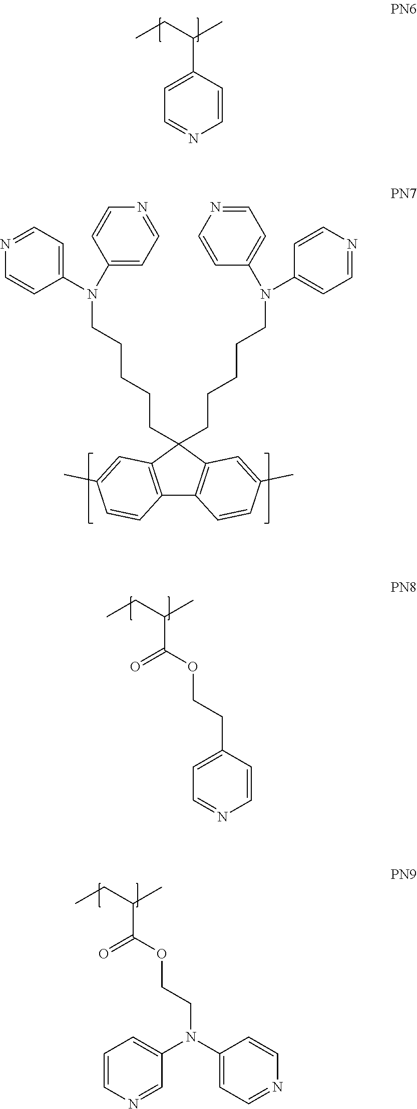

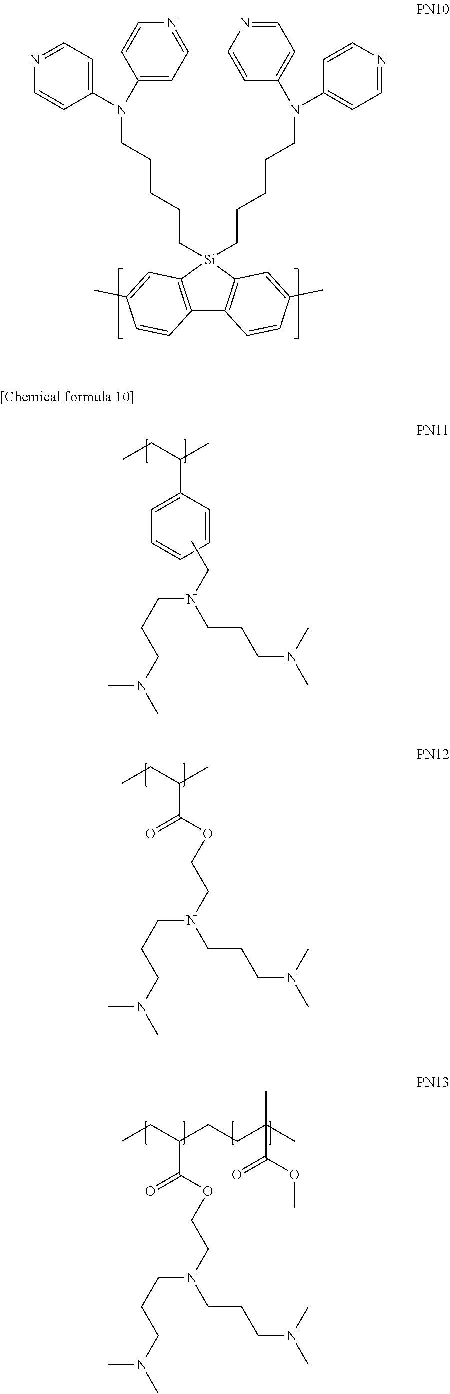

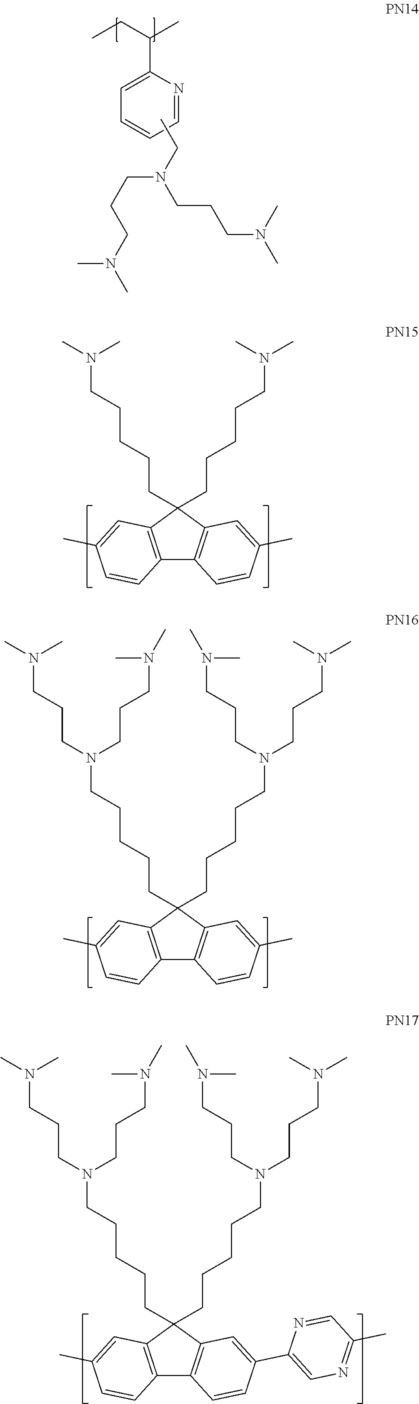

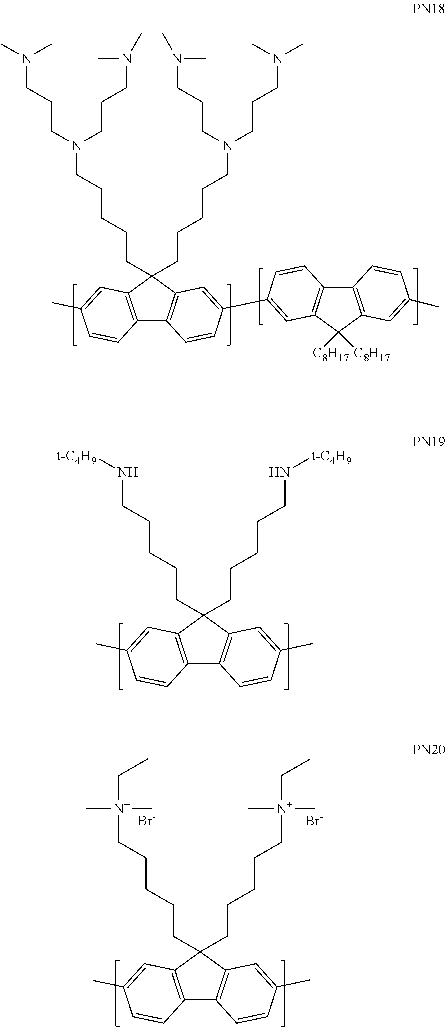

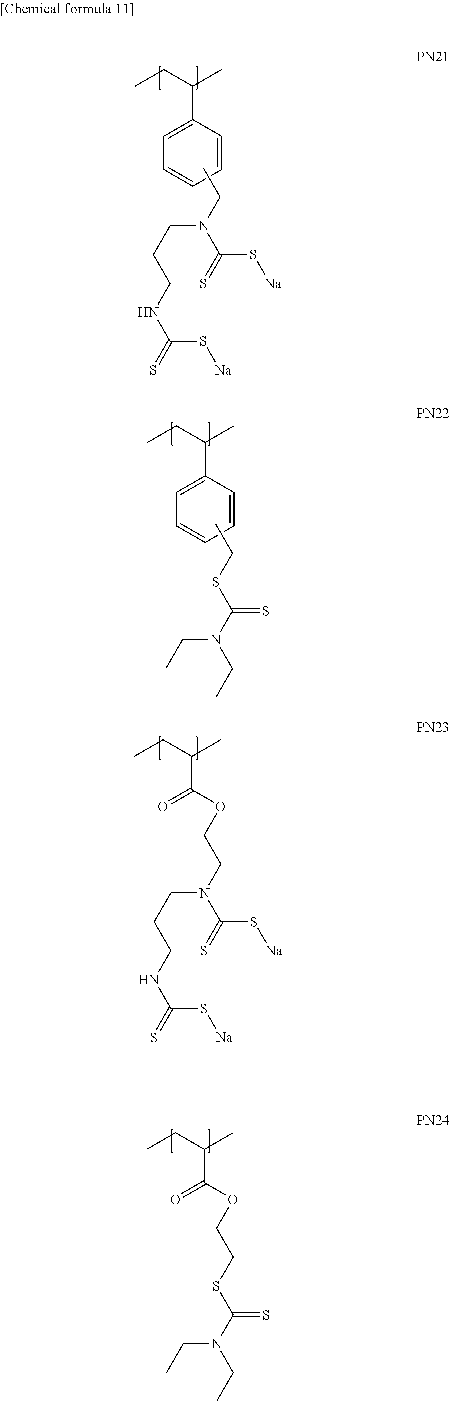

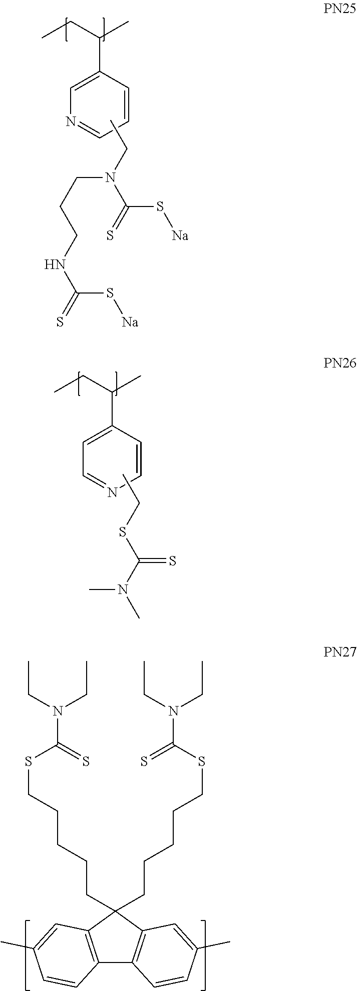

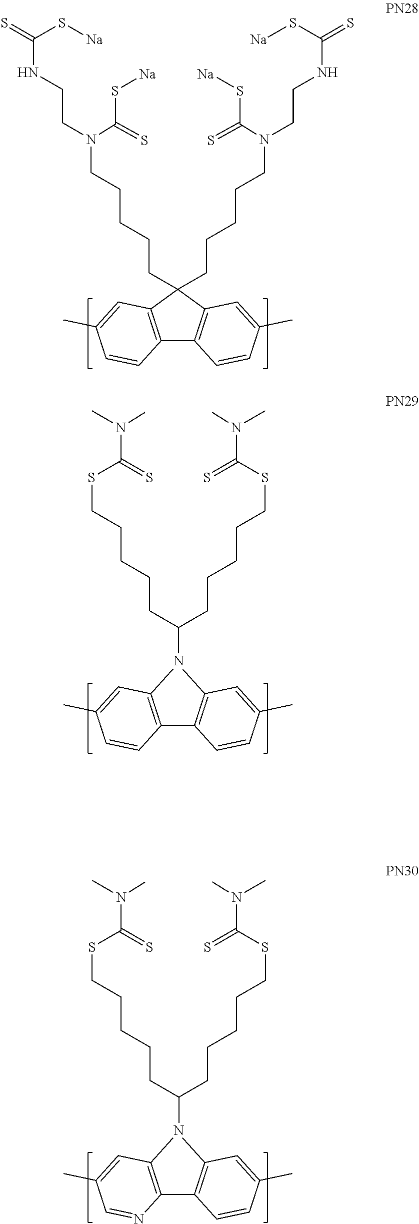

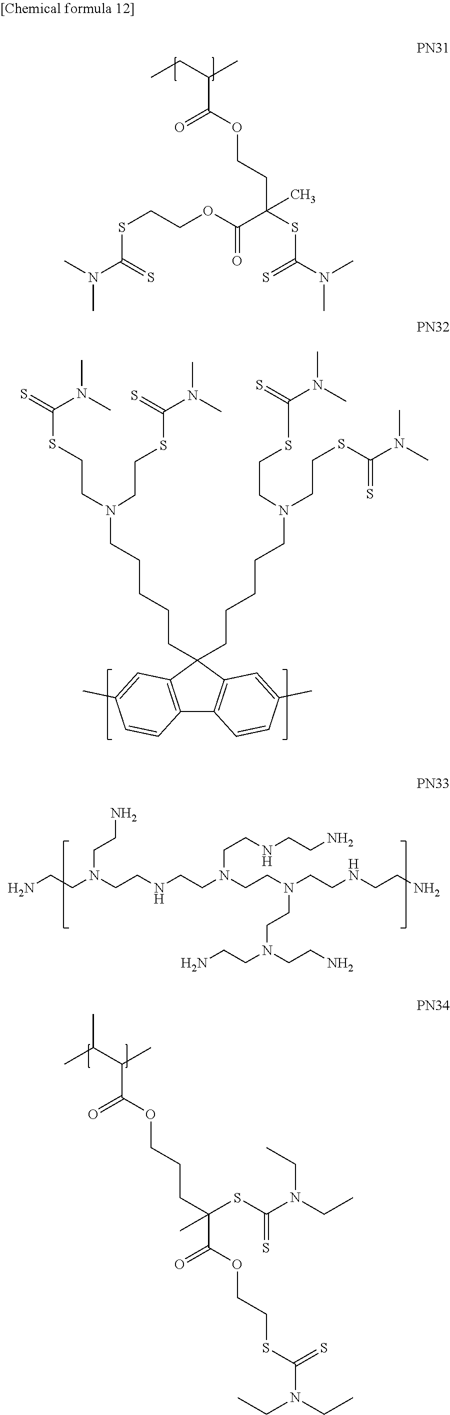

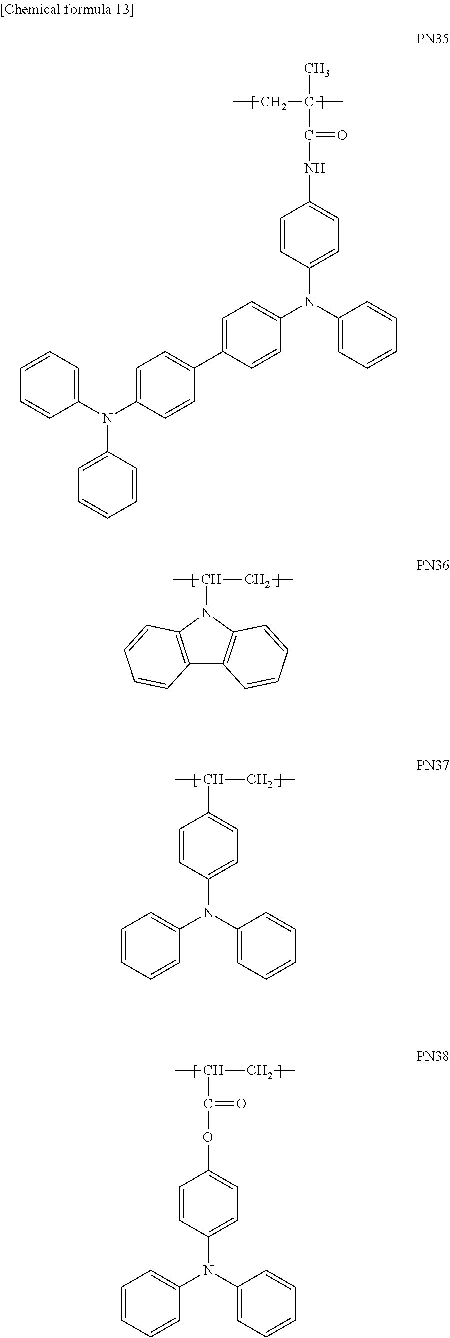

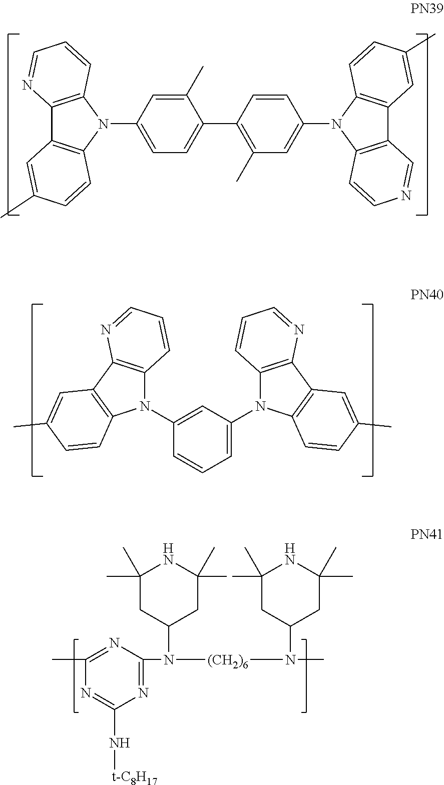

### 3. Organic Compound Containing Sulfur Atom

The organic compound containing a sulfur atom may have, in the molecule, sulfide bond (also referred to as thioether bond), disulfide bond, mercapto group, sulfone group, thiocarbonyl bond, and the like, particularly preferable is sulfide bond or mercapto group.

Specific examples can include the following sulfur-containing compound represented by the following General formula (1) to the General formula (4).

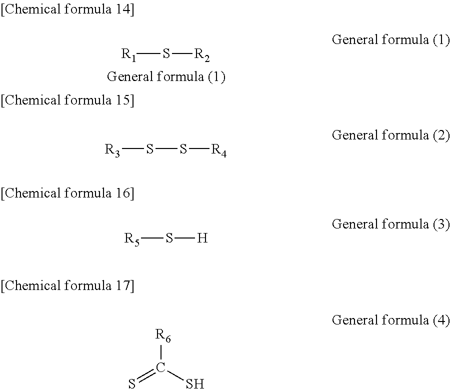

In the above General formula (1), each of R₁ and R₂ represent a substituent.

Examples of the substituent represented by R₁ and R₂ include an alkyl group (e.g., methyl, ethyl, propyl, isopropyl, tert-butyl, pentyl, hexyl, octyl, dodecyl, tridecyl, tetradecyl, pentadecyl, or the like), a cycloalkyl group (e.g., cyclopentyl, cyclohexyl, or the like), an alkenyl group (e.g., vinyl, allyl, or the like), an alkynyl group (e.g., ethynyl, propargyl, or the like), an aromatic hydrocarbon group (also referred to as an aromatic carbon ring group, aryl group, or the like, e.g., phenyl, p-chlorophenyl, mesityl, tolyl, xylyl, naphthyl, anthryl, azulenyl, acenaphthenyl, fluorenyl, phenanthryl, indenyl, pyrenyl, biphenylyl, or the like), an aromatic heterocyclic group (e.g., furyl, thienyl, pyridyl, pyridazinyl, pyrimidinyl, pyrazinyl, triazinyl, imidazolyl, pyrazolyl, thiazolyl, quinazolinyl, carbazolyl, carbolinyl, diazacarbazolyl (refers to a group obtained by replacing, with a nitrogen atom, one of arbitrary carbon atoms constituting a carboline ring of the carbolinyl group), phthalazinyl, or the like), a heterocyclic group (e.g., pyrrolidyl, imidazolidyl, morpholinyl, oxazolidyl, or the like), an alkoxy group (e.g., methoxy, ethoxy, propyloxy, pentyloxy, hexyloxy, octyloxy, dodecyloxy, or the like), a cycloalkoxy group (e.g., cyclopentyloxy, cyclohexyloxy, or the like), an aryloxy group (e.g., phenoxy, naphthyloxy, or the like), an alkylthio group (e.g., methylthio, ethylthio, propylthio, pentylthio, hexylthio, octylthio, dodecylthio, or the like), a cycloalkylthio group (e.g., cyclopentylthio, cyclohexylthio, or the like), an arylthio group (e.g., phenylthio, naphthylthio, or the like), an alkoxycarbonyl group (e.g., methyloxycarbonyl, ethyloxycarbonyl, butyloxycarbonyl, octyloxycarbonyl, dodecyloxycarbonyl, or the like), an aryloxycarbonyl group (e.g., phenyloxycarbonyl, naphthyloxycarbonyl, or the like), a sulfamoyl group (e.g., aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, 2-pyridylaminosulfonyl, or the like), an acyl group (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, pyridylcarbonyl, or the like), an acyloxy group (e.g., acetyloxy, ethylcarbonyloxy, butylcarbonyloxy, octylcarbonyloxy, dodecylcarbonyloxy, phenylcarbonyloxy, or the like), an amido group (e.g., methylcarbonylamino, ethylcarbonylamino, dimethylcarbonylamino, propylcarbonylamino, pentylcarbonylamino, cyclohexylcarbonylamino, 2-ethylhexylcarbonylamino, octylcarbonylamino, dodecylcarbonylamino, phenylcarbonylamino, naphthylcarbonylamino, or the like), a carbamoyl group (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, 2-pyridylaminocarbonyl, or the like), an ureido group (e.g., methylureido, ethylureido, pentylureido, cyclohexylureido, octylureido, dodecylureido, phenylureido, naphthylureido, 2-pyridylaminoureido, or the like), a sulfinyl group (e.g., methylsulfinyl, ethylsulfinyl, butylsulfinyl, cyclohexylsulfinyl, 2-ethylhexylsulfinyl, dodecylsulfinyl, phenylsulfinyl, naphthylsulfinyl, 2-pyridylsulfinyl, or the like), an alkylsulfonyl group (e.g., methylsulfonyl, ethylsulfonyl, butylsulfonyl, cyclohexylsulfonyl, 2-ethylhexylsulfonyl, dodecylsulfonyl, or the like), an arylsulfonyl or heteroarylsulfonyl (e.g., phenylsulfonyl, naphthylsulfonyl, 2-pyridylsulfonyl, or the like), an amino group (e.g., amino, ethylamino, dimethylamino, butylamino, cyclopentylamino, 2-ethylhexylamino, dodecylamino, anilino, naphthylamino, 2-pyridylamino, piperidyl (also referred to as piperidinyl), 2,2,6,6-tetramethylpiperidinyl, or the like), a halogen atom (e.g., fluorine atom, chlorine atom, bromine atom, or the like), a fluorinated hydrocarbon group (e.g., fluoromethyl, trifluoromethyl, pentafluoroethyl, pentafluorophenyl, or the like), cyano, nitro, hydroxy, mercapto, a silyl group (e.g., trimethylsilyl, triisopropylsilyl, triphenylsilyl, phenyldiethylsilyl, or the like), a phosphate group (e.g., dihexylphosphoryl, or the like), a phosphite group (e.g., diphenylphosphinyl, or the like), phosphono, and the like.

In the above General formula (2), R₃ and R₄ represent a substituent.

Examples of the substituent represented by R₃ and R₄ are the same substituents as those of R₁ and R₂.

In the above General formula (3), R₅ represents a substituent.

Examples of the substituent represented by R₅ are the same substituents as those of R₁ and R₂.

In the above General formula (4), the R₆ represents a substituent.

Examples of the substituent represented by the R₆ are the same substituents as those of the R₁ and R₂.

Examples of the organic compound containing sulfur atom which is applicable to the base layer according to the present invention are described below.

Examples of the compound represented by the General formula (1) are the following 1-1 to 1-9.

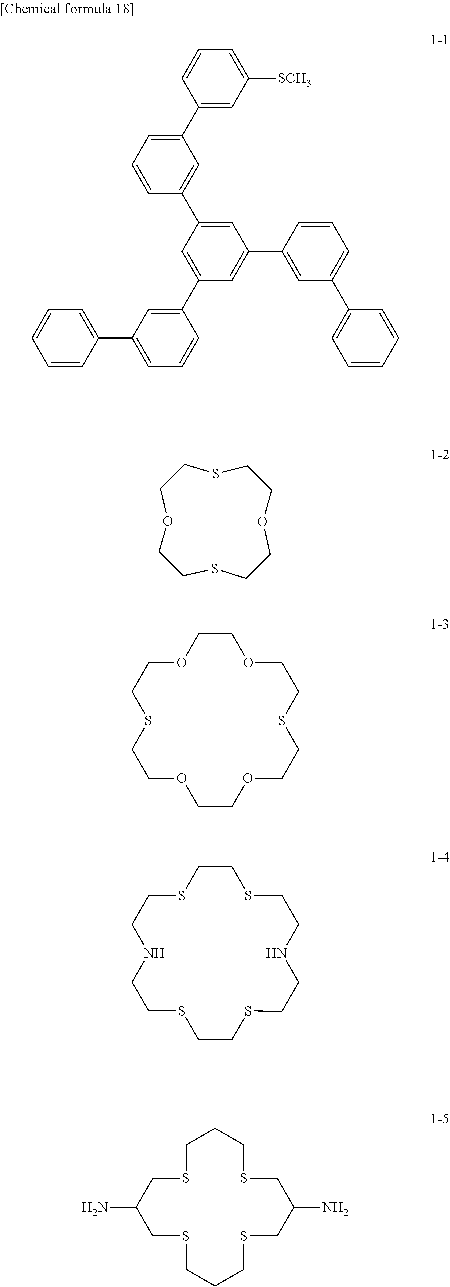

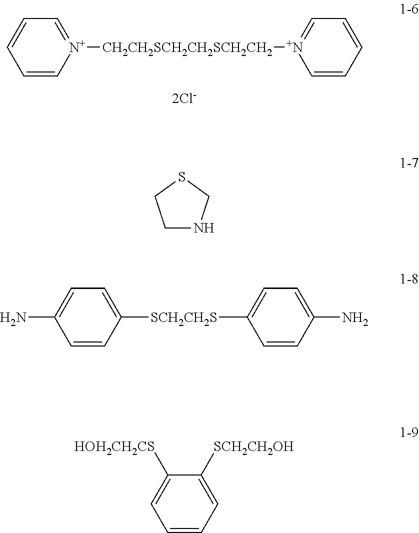

Examples of the compound represented by the General formula (2) are the following 2-1 to 2-11.

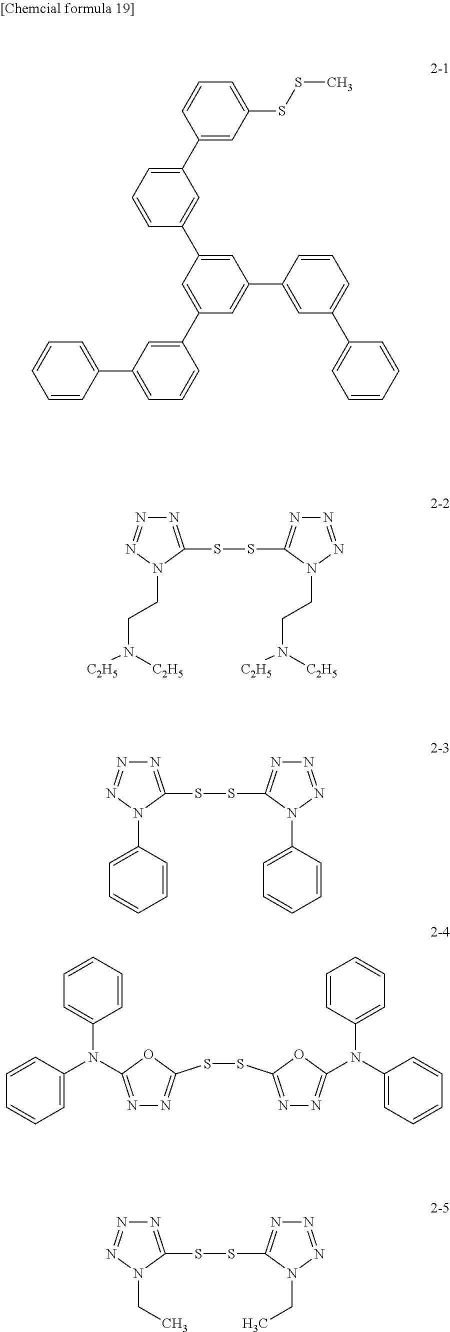

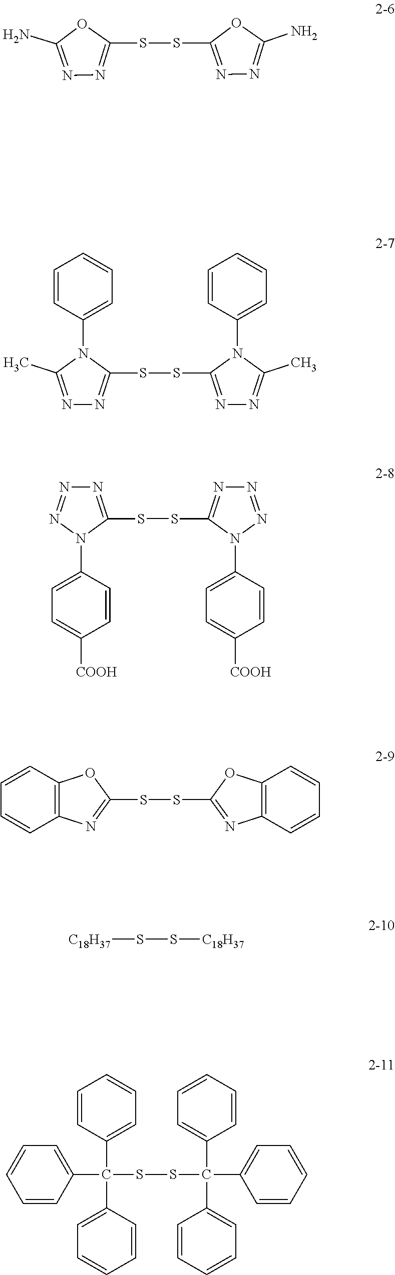

Examples of the compound represented by the General formula (3) are the following 3-1 to 3-23.

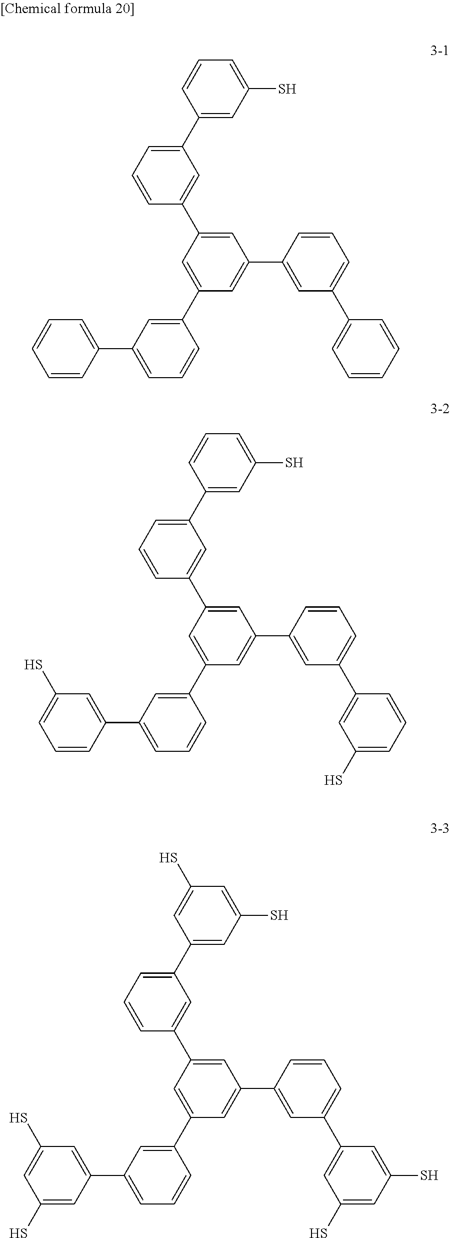

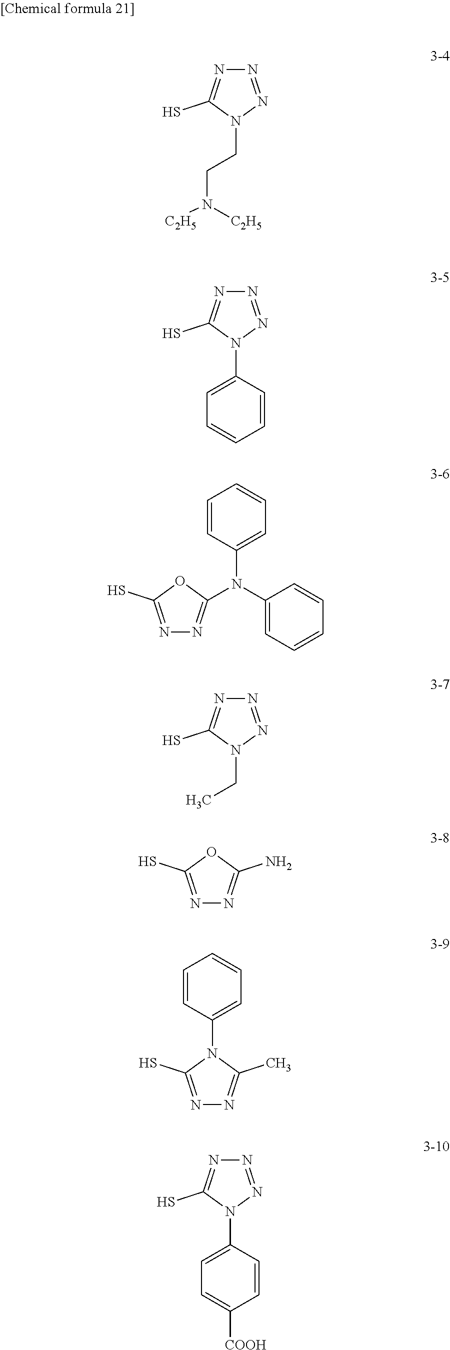

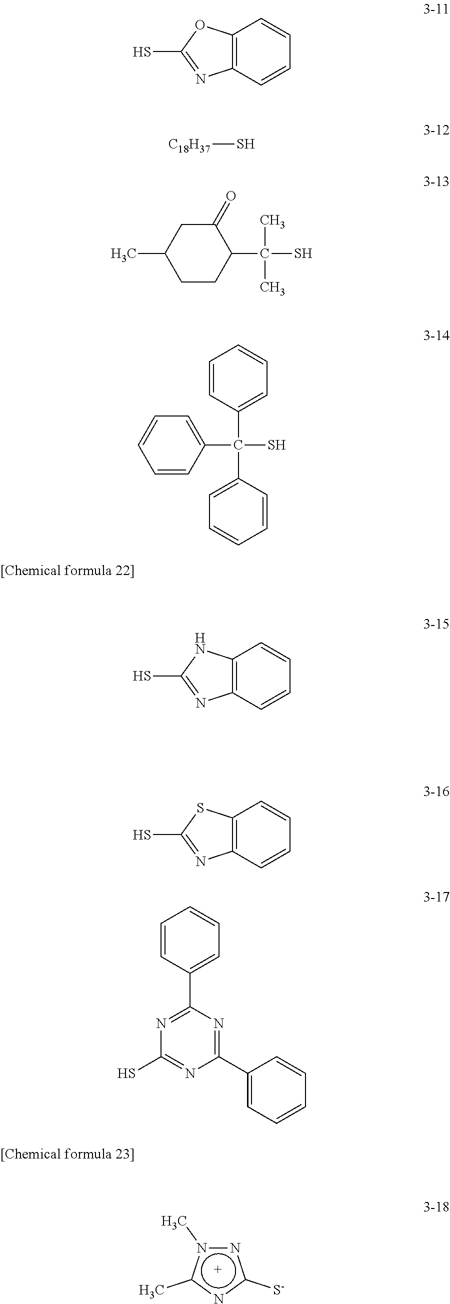

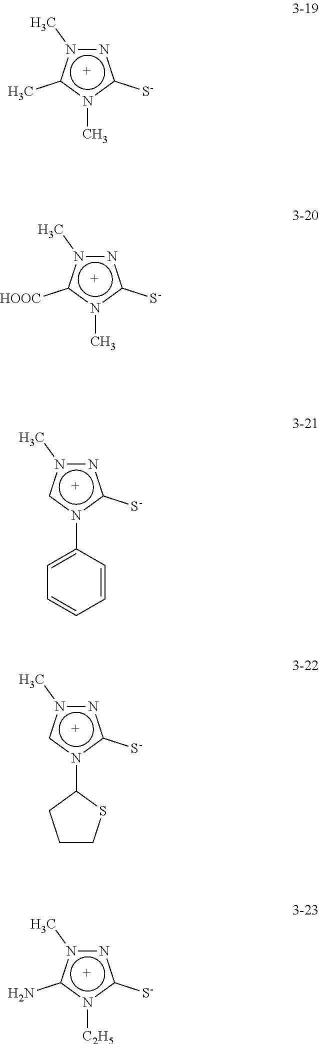

Furthermore, examples of the compound represented by the General formula (4) are the following 4-1.

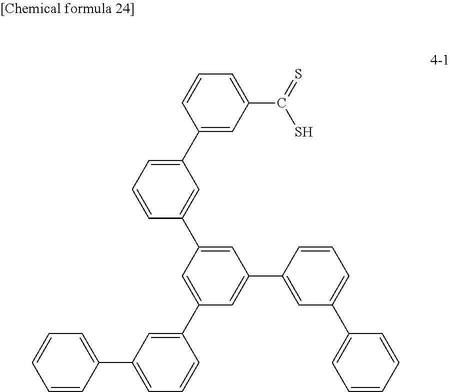

### 4. Polymer Containing Sulfur Atom

The following examples of the polymer containing sulfur atom can be used as the organic compound containing sulfur atom which is applicable to the base layer.

The weight average molecular weight of the polymer containing sulfur atom is preferably within the range of 1000 to 1000000.

The polymer is not particularly limited, and for example, is the polymer composed of the following monomer unit. Note that the numeral mentioned outside the parenthesis represents the structural ratio of each monomer unit (molar ratio).

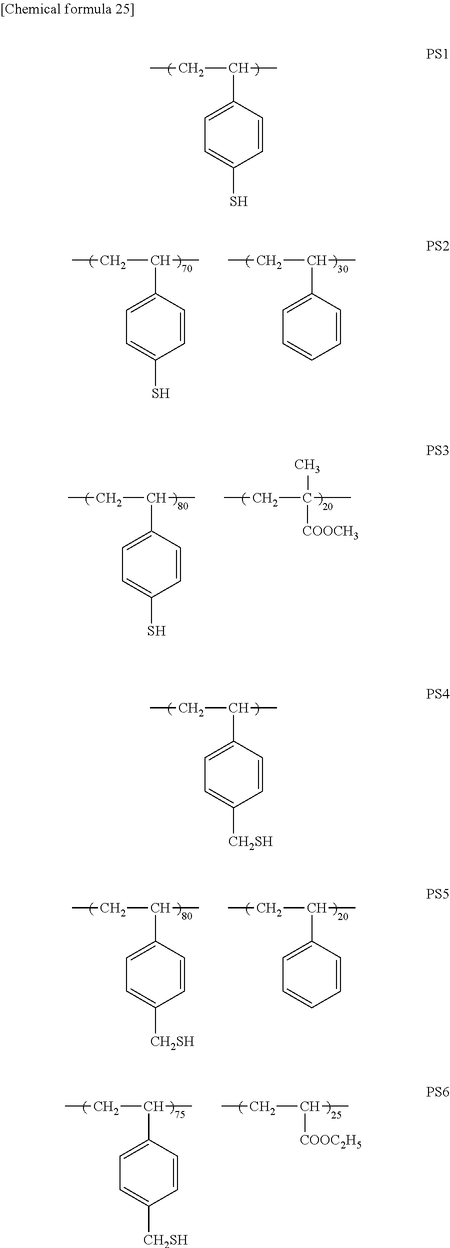

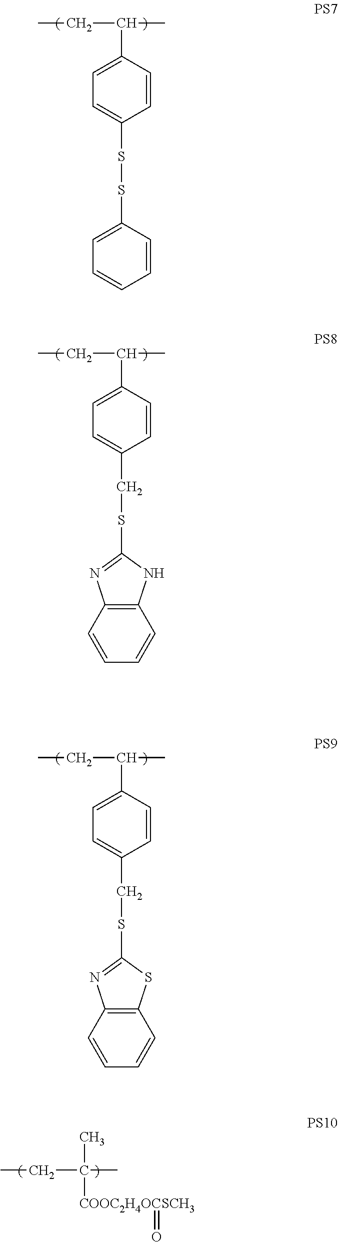

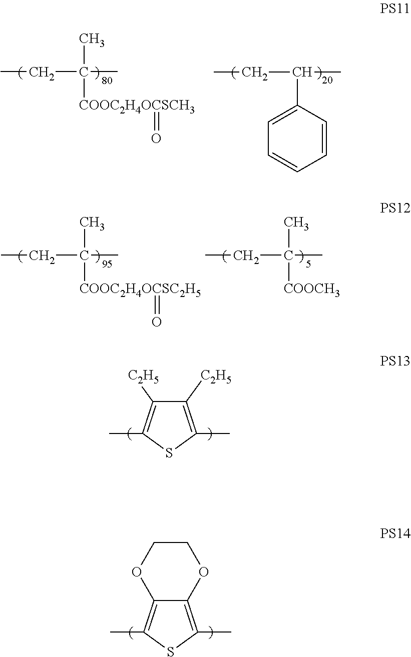

The weight-average molecular weight of the polymer containing sulfur atom described above is shown in the following Table 2.

TABLE 2

| Sulfur atom-containing | Weight-average |
|---|---|
| polymer | molecular weight [Mv] |
| PS1 | 2000 |
| PS2 | 4000 |
| PS3 | 10000 |
| PS4 | 150000 |
| PS5 | 50000 |
| PS6 | 7000 |
| PS7 | 6000 |
| PS8 | 5000 |
| PS9 | 10000 |
| PS10 | 100000 |
| PS11 | 70000 |
| PS12 | 50000 |
| PS13 | 1000 |
| PS14 | 6000 |

The polymer containing sulfur atom can be prepared according to the well-known synthetic method. Furthermore, the polymer containing a sulfur atom preferably has, as described above, a weight-average molecular weight of 1000 to 1000000.

The methods for forming the base layer include a method using a wet process such as an application method, an inkjet method, a coating method or a dipping method, a method using a dry process such as a deposition method (resistance heating, EB method, etc.), a sputtering method or a CVD method, and the like. In addition, the thickness of the base layer is preferably within the range of 5.0 to 40 nm.

<Light-Emitting Functional Layer 3>

The light-emitting functional layer 3 is a layer which includes at least a light-emitting layer 3a composed of an organic material. The whole structure of the light-emitting functional layer 3 is not limited, and may be a general layer structure. One example of the light-emitting functional layer 3 has a configuration in which the [positive hole injection layer/positive hole transport layer/light-emitting layer 3a/electron transport layer/electron injection layer] are laminated from the electrode side which is used as an anode among the transparent electrode 2 and the counter electrode 5, and the layers other than the light-emitting layer 3a may be provided as necessary.

Among them, the light-emitting layer 3a is a layer where the electron injected from the cathode side and the positive hole injected from the anode side are recombined to emit light, and the part to be emitted may be in the light-emitting layer 3a or in an interface between the light-emitting layer 3a and the adjacent layer. In the light-emitting layer 3a, the light-emitting materials may contain a phosphorescent material, a fluorescent material, or both of the phosphorescent material and the fluorescent material. Furthermore, the light-emitting layer 3a preferably has a configuration of using these light-emitting materials as a guest material, and of further containing a host material.

The positive hole injection layer and the positive hole transport layer may be provided as a positive hole transport injection layer having positive hole transporting property and positive hole injecting property. In addition, the electron transport layer and the electron injection layer may be provided as an electron transport injection layer having electron transporting property and electron injecting property. Furthermore, among these layers, there is a case where the positive hole injection layer and the electron injection layer is formed by, for example, an inorganic material.

Moreover, in the light-emitting functional layer 3, in addition to these layers, as necessary, there may be laminated a positive hole-blocking layer, an electron blocking layer, and the like at required positions.

Furthermore, the light-emitting functional layer 3 has a configuration in which a plurality of light-emitting functional layers, each of which contains a light-emitting layer 3a which generates emission light of each color in the respective wavelength region is laminated. Each light-emitting functional layer may have a different layer configuration, or may be directly laminated or may be laminated via an intermediate layer. The intermediate layer is generally any one of an intermediate electrode, an intermediate conductive layer, an electric charge-generating layer, an electron-withdrawing layer, a connecting layer or an intermediate insulation layer, and any known material can be used unless the layer has functions of supplying an electron to the adjacent layer on the anode side and of supplying a positive hole to the adjacent layer on the cathode side.

<Sealing Member>

It is preferable to seal, with a sealing member, the organic EL element 10 of the present invention in order to shield, from the outside air, the transparent electrode 2, the counter electrode 5, and the light-emitting functional layer 3 which is formed between the counter electrode 5 and the transparent electrode 2.

For example, the sealing means used in the present invention can include a method in which the sealing member and the structural members of the above organic EL element 10 are caused to adhere by formation of a sealing resin layer through the use of an adhesive.

The sealing member may be arranged so as to cover the exposed portion of the light-emitting functional layer 3 of the organic EL element 10, and may have a concave shape or a flat shape. Furthermore, there is no particular restriction on the transparency and electric insulation.

Specific examples of the sealing member used for sealing include a glass plate, a polymer plate or film, a metal plate or film, and the like. Examples of the glass plates can include soda-lime glass, barium/strontium-containing glass, lead glass, aluminosilicate glass, borosilicate glass, barium borosilicate glass, quartz, and the like. In addition, examples of the polymer plates can include polycarbonate, acrylate, polyethylene terephthalate, polyether sulfide, polysulfone, and the like. Examples of the metal plates include one or more metal or alloy plate selected from the group consisting of stainless steel, iron, copper, aluminum, magnesium, nickel, zinc, chromium, titanium, molybdenum, silicon, germanium and tantalum.

According to the present invention, since the organic EL element 10 can be made thin, the polymer film or the metal film is preferably used. Furthermore, the polymer film preferably has an oxygen transmission rate of 1×10⁻³ ml/(m²·24 h·atm) or less measured by the method in accordance with JIS K 7126-1987, and a water vapor transmission rate of 1×10⁻³ g/(m²·24 h) or less (25±0.5° C., relative humidity (90±2)% RH) measured by the method in accordance with JIS K 7129-1992.

When the sealing member is processed into a concave shape, a sand blasting, a chemical etching, or the like is used.

Specific examples of the adhesives for forming the sealing resin layer can include a photo-curing or thermosetting adhesive having a reactive vinyl group such as an acrylic acid-based oligomer or a methacrylic acid-based oligomer, and a moisture-curing or another adhesive such as 2-cyanoacrylic acid ester. In addition, the adhesive can include adhesives of a thermosetting and chemical setting type (two-part mixing type) such as an epoxy type. Additionally, the adhesive can include a hot melt adhesive such as polyamide, polyester, or polyolefin. Furthermore, the adhesive can include a cationic curing or ultraviolet curing epoxy resin adhesive.

Note that, since there is a case where the organic EL element 10 may be degraded by the heat treatment, it is preferable that the adhesive can be subjected to adhesion/curing within a temperature range of room temperature to 80° C. In addition, a desiccant may also be dispersed in the adhesive.

The adhesive may be applied to the sealing member by using a commercially available dispenser, or may be applied by printing such as screen printing.

<Light Extraction Layered Body 15>

The feature of the light extraction layered body composed of the transparent substrate 11 and the light extraction layer 1 (hereinafter, simply referred to as layered body 15) is to have a bending property of generating no crack in the bending test. The generation of no crack in the bending test in the present invention is defined as the fact that, after the bending test is carried out, a crack of the light extraction layer 1 has a crack length of less than 50 μm and a number of cracks of 5 or less, in the surface region of arbitrary 500 μm×500 μm area.

Namely, either a case where there are one or more cracks each having a crack length of 50 μm or more, or a case where there are 6 or more cracks each having a crack length of less than 50 μm is outside the scope of the present invention. Note that the surface region of arbitrary 500 μm×500 μm area is a region where a bending stress is applied at a radius of curvature of 5 mm in the bending test.

Here, it is possible to suppress the extension of the crack with lapse of time, by using the light extraction layer 1 having a crack length of less than 50 μm and a number of cracks of 5 or less, and as shown in the following Examples, the element life can be improved. Hereinafter, the bending test to the present invention will be explained.

FIG. 2 is an explanatory view of the bending test of the layered body of the organic EL element. First, as shown in FIG. 2(A), the transparent substrate 11 side of the layered body 15 is pressed to a cylinder having a diameter of 10 mm.

Next, as shown in FIG. 2(B), the layered body 15 is bent to U-shape under the conditions of a radius of curvature of 5 mm (10 mm in diameter), and a bending angle of 180 degrees, and then returned to the initial state of the flat plate.

After the procedure of 10 cycles is repeated, the surface region of 500 μm×500 μm of the light extraction layer is observed with a commercially available light diffraction microscope, and a crack length and a number of cracks are measured.

### Effect of the First Embodiment

The organic EL element 10 as constituted above has the transparent substrate 11 having a thickness of 3 to 50 μm, and the light extraction layer 1 where the scattering layer 1a and the smoothing layer 1b composed of the resin material and the inorganic material are laminated in this order on the transparent substrate 11. In addition, the smoothing layer 1b is constituted by including the resin material having an elongation percentage of 10% or more in the tensile test of the resin single film. Accordingly, it becomes possible to impart a degree of freedom of the inside deformation such as bending, elongation and shrinkage to the smoothing layer 1b, and thus, in the scattering layer 1a which is adjacent to such a smoothing layer 1b, it becomes possible to alleviate the tensile stress of the scattering layer 1a on the smoothing layer 1b side. Namely, even if the scattering layer 1a is bent at an extremely small radius of curvature, the smoothing layer 1b following the scattering layer 1a can be deformed.

Therefore, the layered body 15 constituted by the transparent substrate 11 and the light extraction layer 1 has a bending property of generating no crack when a surface region of 500 μm×500 μm of the light extraction layer is observed with a light diffraction microscope, in a case where a bending test is performed under conditions of a radius of curvature of 5 mm, a bending angle of 180 degrees, and bending cycles of ten.

Accordingly, each of other functional layers constituting the organic EL element 10 can be deformed by following the bending property of the above layered body 15, and thus, even when being bent at an extremely small radius of curvature, the element life can be improved without impairing the light extraction efficiency.

Furthermore, in a case where the transparent electrode 2 of the organic EL element 10 is composed of Ag as a main component and has a configuration of being provided on the base layer, it is possible to make the total thickness of the element can be made small in addition to the above effects. Accordingly, it is possible to impart a degree of freedom of the bending property to the element.

### 2. Second Embodiment

### Organic EL Element

(Configuration in which Light Extraction Layer Having Scattering Layer and Smoothing Layer Both Having Sea-Island Structure is Provided)

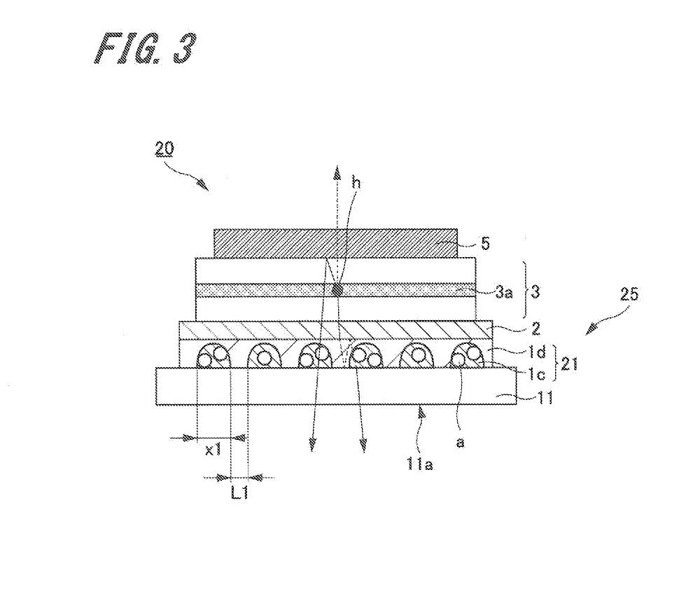

FIG. 3 is a schematic cross-sectional view showing the configuration of the organic EL element according to the second embodiment of the present invention. The organic EL element 20 shown in FIG. 3 has the same other configurations as those of the organic EL element 10 except that only the configuration of the light extraction layer is different from that of the organic EL element 10 explained by referring to FIG. 1. Hereinafter, there will be explained the characteristic parts of the organic EL element 20 according to the second embodiment by attachment of the same symbol to the same constituent elements as in the first embodiment, and by omission of the duplicated explanation.

In the organic EL element 20 of the second embodiment, the transparent substrate 11, the transparent electrode 2, the counter electrode 5, the light-emitting functional layer 3 and the sealing member have the similar configurations to those of the first embodiment. Therefore, detailed explanations of these configurations are omitted.

<Light Extraction Layer 21>

The light extraction layer 21 of this embodiment is constituted by laminating a scattering layer 1c and a smoothing layer 1d in this order, and is characterized in that the scattering layer 1c has the sea-island structure in which the light scattering materials are dispersed in the form of island on the transparent substrate 11.

### 1. Scattering Layer 1c

### Light Extraction Layer 21

The scattering layer 1c is configured to have the sea-island structure in which the light scattering materials are dispersed in the form of island on the transparent substrate 11. Note that the same material as that in the first embodiment can be used as the light scattering material used for the scattering layer 1c.

(1.1 Sea-Island Structure)

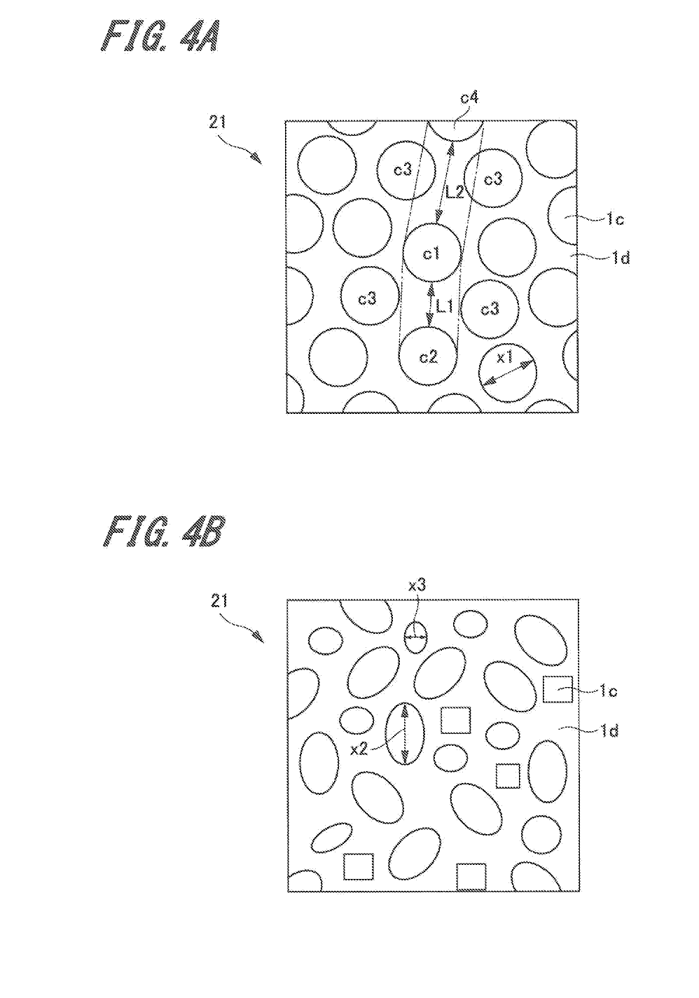

FIG. 4 is a schematic plane view showing the scattering layer of the organic EL element according to the second embodiment of the present invention. As shown in FIG. 3 and FIG. 4, the scattering layer 1c is a layer which is constituted to have the sea-island structure in which the light scattering materials are dispersed in the form of island.

The sea-island structure means a structure in a state where a portion that appears to be relatively continuous is defined as a sea, and the other portion that discontinuously exists therein is defined as an island, and these portions exist in a mixed manner.

Here, the island (hereinafter, referred to as island portion) is composed of the light scattering material, and is one portion that discontinuously exists within the surface on the transparent substrate 11. The light scattering material is composed of the binder and the light scattering particle a, as described above.

Furthermore, the state where the scattering materials are dispersed in the form of island means that: the scattering materials are arranged on the transparent substrate 11 while being kept at desired intervals; and the scattering materials may be regularly arranged or may be irregularly arranged.

The shape of the island may be either regular form or indeterminate form, and, for example, circle, ellipse, square, star, or the like, but is not limited thereto. The size of the islands may be the same as or different from one another, and a plurality of sizes may be mixed.

Furthermore, as shown in FIG. 3, within the surface of the transparent substrate 11, a diameter x1 of the island is preferably formed within the range of 10 μm or more and 100 μm or less. When the diameter is 100 μm or less, even by bending at an extremely small radius of curvature, it becomes possible to prevent the peeling-off generated by the compression stress in the interface between the transparent substrate 11 and the scattering layer 1c, and the cracking generated by the tensile stress on the surface of the scattering layer 1c. Moreover, when the diameter of the island is 10 μm or more, sufficient light extraction efficiency can be obtained in addition to the prevention of the peeling-off and cracking of the scattering layer 1c.

Note that the diameter x1 of the island portion may be the same, or the island portions having a plurality of diameters may be mixed. Furthermore, as shown in FIG. 4B, when the shape of the island portion is indeterminate, the longest line segment x2 and the shortest line segment x3 in the plane of the island portion is defined within the above range. Here, the longest line segment x2 is defined as the longest line segment when arbitrary two different points on the circumferential line of the island portion are connected to each other. Furthermore, the shortest line segment x3 is defined as the shortest line segment.

Moreover, it is preferable that the interval of the island portions is formed so that the interval between the adjacent island portions is 10 μm or less. Here, the interval between the adjacent islands means, as shown in FIG. 4A, an interval L1 from the circumferential line of an arbitrary island portion c1 to other island portion c2, and means an interval in a case where the further other island portion c3 is not superimposed between the arbitrary island portion and the other island portion c2.

In addition, in the straight advancing direction of certain light, in the interval L1, an arbitrary island portion may exist on the light pass in a distance in which the light is not attenuated. In addition, it is more preferable that, for example, an interval L2 in a case where the further other island portion c3 is superimposed between the arbitrary island portion c1 and the other island portion c4 is also within the above range. Namely, it may be possible that an average value of the distance from the circumferential line of the arbitrary island portion c1 to the other island portion is within the above range.

Furthermore, the thickness of the scattering layer 1c is, depending on the size of the light scattering particle a which constitutes the scattering layer and the kind of material of the binder, 150 to 500 nm, preferably 150 to 300 nm from the viewpoint of the light extraction efficiency and the flexibility. In addition, from the viewpoint of the flexibility, the scattering layer is preferably formed as thin as possible, and for example, from the viewpoint of the light extraction efficiency, it is more preferable that the scattering layer has a thickness of approximately an average particle size so that the light scattering particle a makes contact with or is adjacent to the interface between the scattering layer 1c and the smoothing layer 1d.

### 2. Smoothing Layer 1d

### Light Extraction Layer 21

The smoothing layer 1d is a layer that makes the surface facing the transparent electrode 2 flat by embedding the convex and concave structure (sea-island structure) of the surface of the scattering layer 1c.

Note that the material constituting the smoothing layer 1d may be the same as or different from the material of the smoothing layer 1b of the organic EL element 10 shown in FIG. 1. Namely, even if the layer can make the surface of the scattering layer 1c flat, and is a high refractive index layer having a refractive index of 1.7 or more and less than 2.5, and does not inhibit the functions of the organic EL element 20, the smoothing layer may be constituted of the material usable as the binder of the above scattering layer 1a and the inorganic material of the smoothing layer 1b.

Furthermore, the thickness of the smoothing layer 1d is not particularly limited, and is preferably formed as thin as possible within the range in which the convex and concave structure (sea-island structure) of the surface of the scattering layer 1c can be sufficiently embedded. From the viewpoint of the light transmittance and the flexibility, as to the thickness of the smoothing layer 1d, it is preferable that the thickness of the light extraction layer 21 which is a total thickness of the scattering layer 1c and the smoothing layer 1d is 1 μm or less. The thickness of the smoothing layer 1d is a thickness from the surface of the transparent substrate 11 at the portion where the scattering layer 1c is not formed.

### 3. Method of Forming Light Extraction Layer 21

The light extraction layer 21 can be formed in the same way as in the above-described light extraction layer 1 of the organic EL element 10. Note that the sea-island structure of the scattering layer 1c is formed by printing the coating solution of scattering layer through the use of an inkjet method or a super inkjet method in the coating-patterning treatment (i). Furthermore, the sea-island structure of the scattering layer is so formed that the diameter of the island after drying is within the range of 10 μm or more and 100 μm or less, and an interval between the islands is 10 μm or less.

### Effect of the Second Embodiment

The organic EL element 20 as constituted above has the transparent substrate having a thickness of 3 to 50 μm, and the light extraction layer 21 where the scattering layer 1c and the smoothing layer 1d are laminated in this order on the transparent substrate. Since particularly, the scattering layer 1c has the sea-island structure in which the light scattering material is dispersed in the form of the island, for example, it becomes possible to alleviate the tensile stress on the smoothing layer 1d side of the scattering layer 1c, in comparison with a scattering layer which is formed as a continuous film. Thereby, it is possible to impart a degree of freedom of the deformation such as bending, elongation and shrinkage to the scattering layer 1c, and to bend the scattering layer 1c at an extremely small radius of curvature.

Therefore, as explained in the first embodiment by referring to FIG. 2, the layered body 25 constituted by the transparent substrate 11 and the light extraction layer 21 has a bending property of generating no crack when a surface region of 500 μm×500 μm of the light extraction layer is observed with a light diffraction microscope, in a case where a bending test is performed under conditions of a radius of curvature of 5 mm, a bending angle of 180 degrees, and bending cycles of ten.

Accordingly, each of other functional layers constituting the organic EL element 20 can be deformed by following the bending property of the above layered body 25, and thus, even when being bent at an extremely small radius of curvature, the element life can be improved without impairing the light extraction efficiency.

Furthermore, in a case where the smoothing layer 1d of the organic EL element 20 is formed by using the same material as that of the smoothing layer 1b explained by referring FIG. 1, it becomes possible to impart a degree of freedom of the inside deformation such as bending, elongation and shrinkage to the smoothing layer, and the organic EL element is difficult to be broken due to the synergy effect with the scattering layer 1c in addition to the above effects, and furthermore, the element life can be improved without impairing the light extraction efficiency.

Moreover, in a case where the transparent electrode 2 of the organic EL element 20 is composed of Ag as a main component and has a configuration of being provided on the base layer, it is possible to make the total thickness of the element small in addition to the above effects explained in the first embodiment. Accordingly, it is possible to impart a degree of freedom of the bending property to the element.

### 3. Third Embodiment

### Method of Manufacturing Organic EL Element

Here, the method of manufacturing the organic EL element 10 shown in FIG. 1 will be explained as one example.

First, the transparent substrate 11 is prepared, and the scattering layer 1a is formed thereon by using the above described manner. The scattering layer 1a is formed by, after coating of a coating solution of scattering layer containing the light scattering particles a having an average particle size of 150 to 350 nm on the transparent substrate 11, drying of the resultant coated substance, and, then, as necessary, the curing treatment. The formation conditions of the scattering layer 1a are that the formed scattering layer 1a has an inplane occupancy of the light scattering particles a of 20 to 60%, a layer thickness of 150 to 500 nm, a surface roughness Ra of 150 to 350 nm and a maximum height Rt of 100 to 300 nm. Next, the smoothing layer 1b is formed on the scattering layer 1a by a coating method. The smoothing layer 1b is formed, in the same way as in the formation of the scattering layer 1a, by, after coating of the coating solution of smoothing layer on the scattering layer 1a, drying of the resultant coated substance, and the curing treatment. In this way, the light extraction layer 1 constituted by the scattering layer 1a and the smoothing layer 1b is formed on the transparent substrate 11.

Next, after forming the base layer (layer containing a nitrogen atom) as necessary, the transparent electrode 2 for the anode is formed by using a given electrode material and by an appropriate method such as vapor deposition method. At the same time, a lead electrode not shown in the figure which is connected to the external device is formed at the end of the transparent electrode 2 by an appropriate method such as vapor deposition method.

Subsequently, for example, the positive hole injection layer, the positive hole transport layer, the light-emitting layer 3a, the electron transport layer and the electron injection layer are formed in the order, with the result that the light-emitting functional layer 3 is formed on the transparent electrode.

In the formation of the layers, there are used a spin coating method, a casting method, an inkjet printing method, a vapor deposition method, a sputtering method, a printing method, and the like, and from the viewpoints that a homogeneous layer can easily be obtained and a pinhole is hard to be generated, the vacuum vapor deposition method or the spin coating method is particularly preferable. Furthermore, a different forming method may be applied to each layer. When the vapor deposition method for formation of each layer is employed, although the vapor deposition conditions are varied depending on the kind of the compound to be used, it is desirable to appropriately select each condition from the ranges of a heating temperature of boat of 50 to 450° C., a degree of vacuum of 1×10⁻⁶ to 1×10⁻² Pa, a vapor deposition rate of 0.01 to 50 nm/sec, a temperature of substrate of −50 to 300° C., and a thickness of membrane of 0.1 to 5 μm.

Preferably, in the light-emitting functional layer 3, it is better that the region to be formed is almost completely superimposed with the position (region) where the light extraction layer 1 is formed in the cross-sectional view, and thus, the emitted light h which is generated in the light-emitting functional layer 3 can be effectively extracted through the light extraction layer 1.

After formation of the light-emitting functional layer 3 in the above, a counter electrode 5 which serves as a cathode is formed thereon by an appropriate formation method such as vapor deposition method or sputtering method. At this time, in the counter electrode 5, pattern formation is performed in the form in which a terminal portion is pulled out from upper side of the light-emitting functional layer 3 to the peripheral of the transparent substrate 11, while an insulation state is kept with respect to the transparent electrode 2 by the light-emitting functional layer 3. Accordingly, the organic electroluminescence element 10 is obtained. In addition, after that, there is provided the sealing member that covers at least the light-emitting functional layer 3 in a state where the terminal portions of the transparent electrode 2 (extraction electrode) and the counter electrode 5 of the organic EL element 10 are exposed.

By the above procedures, a desired organic EL element 10 is obtained on the transparent substrate 11. In the production of the organic EL element 10, although it is preferable to consistently carry out production from the light-emitting functional layer 3 to the counter electrode 5 by one time vacuum suction, it may be possible that the transparent substrate 11 is taken out from the vacuum atmosphere to be subjected to other different formation. At that time, consideration of performing the procedures under a dry inert gas atmosphere, or the like is needed.

In a case of application of a direct voltage to the thus obtained organic EL element 10, while the transparent electrode 2 of the anode is set as + polarity and the counter electrode 5 of the cathode is set as − polarity, a light emission can be observed by application of a voltage of 2 to 40 V to the electrodes. Furthermore, an alternating voltage may also be applied. Note that a waveform of the alternating voltage to be applied may be arbitrary.

### Examples

Hereinafter, the present invention will be explained specifically by the use of the Examples, but the present invention is not limited thereto.

### <<Production of Bottom-Emission Type Organic EL Element>>

Each organic EL element of Samples 101 to 115 was produced so that an area of the light-emitting region was 2.0 cm×2.0 cm. In the following Table 3, the configuration of each layer in each organic EL element of Samples 101 to 115 is shown. The production procedures are explained by referring to FIGS. 1 and 2, and Table 3.

### <Production of Organic EL Element 101>

### 1. Formation of Transparent Electrode

A polyethylene terephthalate film (hereinafter referred to a transparent substrate) having a thickness of 50 μm was overlapped with a mask that has an opening of 20 mm×50 mm in the center and was fixed onto a substrate holder of a commercial vapor deposition apparatus, the compound No. 46 was placed in the resistive heating boat of tungsten, and then the substrate holder and the heating boat were attached to a first vacuum tank of the vacuum vapor deposition apparatus. In addition, silver (Ag) was placed in the resistive heating boat of tungsten, and attached to the second vacuum tank of the vacuum vapor deposition apparatus.

Note that the exemplary compound used here is the above-described compound No. 46 having a nitrogen atom with unshared electron pairs which are not involved in the aromaticity described above.

Next, after a pressure of the first vacuum tank was reduced to 4×10⁻⁴ Pa, the heating boat containing the compound No. 46 was heated by application of an electric current, and then, the base layer having a thickness of 50 nm was formed on the transparent substrate at a deposition rate of 0.1 nm/sec to 0.2 nm/sec.

Subsequently, the transparent substrate on which the layers up to the base layer were formed was transferred to the second vacuum tank under vacuum, and after a pressure of the second vacuum tank was reduced to 4×10⁻⁴ Pa, the heating boat containing silver was heated by application of an electric current. Accordingly, a transparent electrode made of silver having a thickness of 8 nm was formed at a deposition rate of 0.1 nm/sec to 0.2 nm/sec on the base layer.

### 2. Formation of Light-Emitting Functional Layer

The transparent substrate on which the base layer was formed was overlapped with a mask that has an opening of width 30 mm×30 mm in the center and was fixed onto a substrate holder of a commercial vapor deposition apparatus. Furthermore, each of the resistive heating boat made of tungsten of the vacuum vapor deposition apparatus was filled with each material constituting the light-emitting functional layer, in an optimum amount for forming each layer.

Then, after a pressure of the vacuum tank of the vacuum vapor deposition apparatus was reduced to 4×10⁻⁴ Pa, each heating boat containing each material was heated by sequential application of an electric current, and thus each layer was formed in the following way.

(Positive Hole Transport Injection Layer)

First, the heating boat containing α-NPD represented by the following structural formula as a positive hole transport injection material was heated by application of an electric current, and thus a positive hole transport injection layer made of α-NPD and serving both as the positive hole injection layer and the positive hole transport layer was formed on the transparent electrode. At this time, the deposition rate was 0.1 to 0.2 nm/sec, and a thickness was 140 nm.

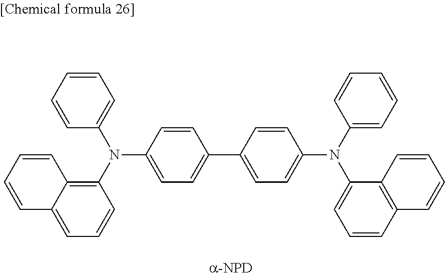 [SMILES: c1ccc(N(c2ccc(-c3ccc(N(c4ccccc4)c4cccc5ccccc45)cc3)cc2)c2cccc3ccccc23)cc1]

(Light-Emitting Layer)

Next, an electric current was independently applied to the resistive heating boat containing the host material H4 represented by the following structural formula and the heating boat containing the phosphorescence emitting compound Ir-4 represented by the following structural formula, and thus a light-emitting layer composed of the host material H4 and the phosphorescence emitting compound Ir-4 was formed on the positive hole transport injection layer. At this time, the electric current to be applied was controlled so as to be a ratio of the deposition rate (nm/sec) of the host material H4 to the phosphorescence emitting compound Ir-4=100:6. The thickness of the light-emitting layer was 30 nm.

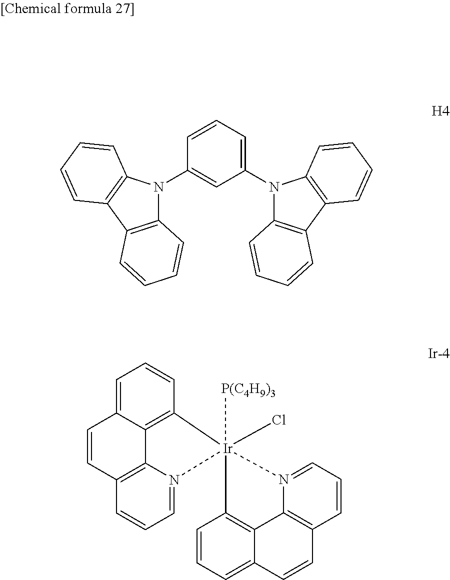

(Positive Hole-Blocking Layer)

Next, the resistive heating boat containing BAlq represented by the following structural formula as a positive hole-blocking material was heated by application of an electric current, and thus a positive hole-blocking layer made of BAlq on the light-emitting layer was formed. At this time, the deposition rate was 0.1 to 0.2 nm/sec, and a thickness was 10 nm.

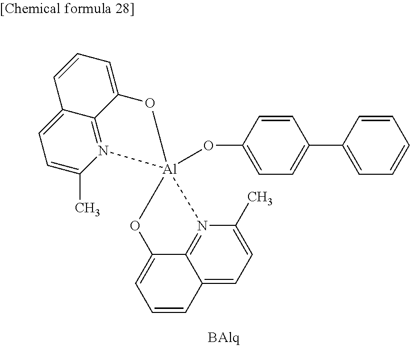

(Electron Transport Layer)

After that, an electric current was independently applied to the resistive heating boat containing the above-described exemplary compound No. 7 as the electron transport material and the resistive heating boat containing potassium fluoride, and thus an electron transport layer composed of the above-described exemplary compound No. 7 and the potassium fluoride was formed on the positive hole-blocking layer. At this time, the electric current to be applied was controlled so as to be a ratio of the deposition rate (nm/sec) of the exemplary compound No. 7:the potassium fluoride=75:25. The thickness of the electron transport layer was 30 nm.

(Electron Injection Layer)

Next, the heating boat containing potassium fluoride was heated by application of an electric current, and thus an electron injection layer composed of potassium fluoride was formed on the electron transport layer. At this time, the deposition rate was 0.01 to 0.02 nm/sec, and a thickness was 1 nm.

### 3. Formation and Sealing of Counter Electrode

After that, the transparent substrate on which the layers up to the electron injection layer were formed was transferred, while the vacuum condition was kept, to the third vacuum tank to which the resistive heating boat of tungsten containing aluminum (Al) was attached. The transparent substrate was overlapped with a mask having an opening width 20 mm×50 mm which was arranged perpendicularly to the transparent electrode (anode), and was then fixed.

Subsequently, in the third vacuum tank, a reflective counter electrode (cathode) of Al having a film thickness of 100 nm was formed at a film forming rate of 0.3 to 0.5 nm/sec.

After that, the organic EL element was covered by a sealing member of a glass substrate having a size of 40 mm×40 mm and a thickness of 700 μm, having a center portion size of 34 mm×34 mm, and being obtained by scraping the center portion so as to have a depth of 350 μm, and a portion between the sealing member and the transparent substrate was filled with an adhesive (sealing material) in a state of enclosing the organic EL element. An epoxy-based photocurable adhesive (Lackstrack LC0629B manufactured by TOAGOSEI) was used as the adhesive.

Thereafter, the adhesive filled in the portion between the sealing member and the transparent substrate was irradiated with UV light from the glass substrate (sealing member) side, and then the organic EL element was sealed by curing the adhesive.

Note that, in the formation of the organic EL element, through the use of a deposition mask for forming each layer, a light-emitting region of 20 mm×20 mm in the center of the transparent substrate of 50 mm×50 mm was set as a light-emitting region, and a non-light-emitting region with a width of 15 mm was provided around the whole peripheral of the light-emitting region.

Furthermore, the transparent electrode as the anode and the counter electrode as the cathode were formed in a state of being insulated by the light-emitting functional layer from the positive hole transport injection layer to the electron transport layer, and the terminal portions were led out to the peripheral of the transparent substrate.

The organic EL element 101 was produced in the above-described way.

<Production of Organic EL Element 102>

The organic EL element 102 was produced in the same procedures as in Sample 101 except that the element was formed by using a transparent substrate having a thickness of 100 μm.

<Production of Organic EL Element 103>

In the following way, the organic EL element 102 was produced in the same procedures as in the above organic EL element 101 except that the scattering layer was formed before forming the transparent electrode.

The scattering layer was formed in the following way by using the following materials.

First, formulation design as the light scattering particle dispersion was performed in a ratio of an amount of 50 ml, by mixing TiO₂ particles having a refractive index of 2.4 and an average particle size of 0.25 μm (JR600A, manufactured by Tayca) and a resin solution (ED230AL (organic inorganic hybrid resin) manufactured by APM corporation) so that the ratio between the TiO₂ particle and the resin component was 95 volume %:5 volume %, a ratio between a mixed solvent of n-propyl acetate and cyclohexanone was 10% by mass:90% by mass, and a concentration of the TiO₂ particle and the resin component was 40% by mass.

Specifically, the TiO₂ dispersion was prepared by mixing of the above TiO₂ particles and the mixed solvent, and by dispersion for 10 minutes under a standard condition of the micro tip step (MS-3 3 mmφ manufactured by SMT) in the ultrasonic dispersing apparatus (UH-50 manufactured by SMT), while being cooled at normal temperature.

Next, the resin solution was added and mixed little by little while the TiO₂ dispersion being stirred at 100 rpm, and after completion of the addition, the resultant solution was stirred for 10 minutes while the stirring rate being raised up to 500 rpm.

Subsequently, a desired light scattering particle dispersion was obtained by filtration with a PVDF 0.45 μm filter (manufactured by Whatman). The concentration of the TiO₂ particle and the resin component was 37.8% by mass, and the average particle size of the dispersed particles was 210 nm (particle size distributer Zetasizer nano-S manufactured by Malvern Instlement Ltd.)

Next, the above light scattering particle dispersion and the resin solution (ED230AL) were mixed so that a value (%) of the volume ratio of the light scattering particle to the resin component×100 (hereinafter, also referred to as “P/B (pigment/binder)” was 90%, and furthermore, a ratio between n-propyl acetate and cyclohexanone was adjusted to 10% by mass:90% by mass, and a concentration of the TiO₂ particle and the resin component was adjusted to be 10% by mass in a ratio of an amount of 10 ml, with the result that a coating solution of scattering layer was obtained.

Then, the coating solution of scattering layer was coated on a prepared transparent substrate by a spin coater. Note that the rotation speed was appropriately regulated so that a thickness after drying was 230 nm.

Thereafter, a scattering layer was formed by simple drying (80° C., 2 minutes) and further drying with a hot plate (120° C., 60 minutes).

<Production of Organic EL Element 104>

In the following way, the organic EL element 104 was produced in the same procedures as in the above organic EL element 103 except that the smoothing layer was formed before formation of the transparent electrode.

Formulation design was performed in a ratio of an amount of 10 ml by mixing the nano TiO₂ particles and a UV curable resin made of epoxyacrylate (Hitaloid 7951 manufactured by Hitachi Chemical Co., Ltd.) so that a ratio between the nano TiO₂ particles and the resin component was 45% by volume:55% by volume, a ratio among n-propyl acetate and cyclohexanone and toluene was 20% by mass:30% by mass:50% by mass, and a concentration of the nano TiO₂ particle and the resin component was 15% by mass.

Specifically, a preparation solution of a smoothing layer was obtained by mixing of the nano TiO₂ dispersion and the solvent, by addition and mixing of the resin solution little by little while stirring at 100 rpm, and after completion of the addition, by stirring the resultant solution for 10 minutes while raising the stirring rate up to 500 rpm. Thereafter, a desired coating solution of a smoothing layer was obtained by filtration with a PVDF 0.45 μm filter, and a PVDF 0.20 μm filter (manufactured by Whatman) in this order.

Next, after film formation was performed by coating the coating solution of smoothing layer on the scattering layer though the use of a spin coater so that a thickness after drying was 500 nm, a smoothing layer was formed by UV irradiation with a high pressure mercury lamp (80 W/cm²) at a dose of 0.4 (J/cm²).

<Production of Organic EL Element 105>

In the following way, the organic EL element 105 was produced in the same procedures as in the above organic EL element 103 except that the scattering layer was formed in the form of the sea-island structure. Note that the sea-island structure of the scattering layer was obtained by printing the above coating solution of scattering layer on a prepared transparent substrate by a super inkjet method. In addition, the sea-island structure of the scattering layer was set so that the island diameter after drying was 200 μm, and the distance between the islands was 20 μm.

<Production of Organic EL Element 106>

The organic EL element 106 was produced in the same procedures as in the above organic EL element 105 except that the island diameter of the sea-island structure of the scattering layer was 80 nm.

<Production of Organic EL Elements 107 to 110>

The organic EL elements 107 to 110 were produced in the same procedures as in the above organic EL element 104 except that the smoothing layer were composed of the respective materials shown in the following Table 3. Note that the resin materials (UV curable resins) constituting the smoothing layer of the organic EL elements 107 to 110 were an acrylic resin acrylate (Hitaloid 7975 manufactured by Hitachi Chemical Co., Ltd.), an acrylic resin acrylate (Hitaloid 7970 manufactured by Hitachi Chemical Co., Ltd.), a urethane acrylate (Hitaloid 4861 manufactured by Hitachi Chemical Co., Ltd.), and a polyurethane acrylate (Hitaloid 7981 manufactured by Hitachi Chemical Co., Ltd.), respectively. In addition, the transparent substrate was formed by using one having a thickness shown in the following Table 3.

<Production of Organic EL Elements 111 to 115>

In the following way, the organic EL elements 111 to 115 were produced in the same procedures as in the above organic EL element 105 except that the smoothing layer was formed before formation of the transparent electrode. Note that the thickness of the transparent substrate, the island diameter and distance between the islands were formed according to the values shown in the following Table 3.

The smoothing layer was formed in the following way by using the following materials.

First, formulation design as the preparation solution of smoothing layer was performed in a ratio of an amount of 50 ml, by mixing nano TiO₂ dispersion having a refractive index of 2.4 and an average particle size of 0.02 μm (HDT-760T, manufactured by Tayca) and a resin solution (ED230AL (organic inorganic hybrid resin) manufactured by APM corporation) so that the ratio between the nano TiO₂ particle and the resin component was 45 volume %:55 volume %, a ratio among n-propyl acetate and cyclohexanone and toluene was 20% by mass:30% by mass:50% by mass, and a concentration of the nano TiO₂ particle and the resin component was 15% by mass.

Specifically, a preparation solution of a smoothing layer was obtained by mixing of the nano TiO₂ dispersion and the solvent, by addition and mixing of the resin solution little by little while stirring at 100 rpm, and after completion of the addition, by stirring the resultant solution for 10 minutes while raising the stirring rate up to 500 rpm. Thereafter, a desired coating solution of a smoothing layer was obtained by filtration with a PVDF 0.45 μm filter, and a PVDF 0.20 μm filter (manufactured by Whatman) in this order.

Next, after the coating solution of smoothing layer was coated on the scattering layer by a spin coater (1000 rpm, 30 seconds), a smoothing layer having a thickness of 450 nm was formed by simple drying (80° C., 2 minutes) and further drying with a hot plate (120° C., 30 minutes). Note that a refractive index of the single layer of the smoothing layer was 1.85.

### Evaluation of Each Organic EL Element of Examples

As to the organic EL elements produced in Samples 101 to 115, the following (1) bending evaluation, (2) uniformity of light emission, (3) electric power efficiency, and (4) light emission life were measured. Note that the (1) bending evaluation is the evaluation in the layered body of the organic EL element. The results are shown in the following Table 3 together.

(1) Bending Evaluation

The transparent substrate side of the layered body where the light extraction layer was formed on the transparent substrate was pressed to a cylinder having a diameter of 10 mm, bent into U-shape at an angle of 180 degrees, and then returned to the initial state of the flat plate. After repeating this procedure 10 cycles, in the surface of the light extraction layer of the layered body, a length of crack and a number of cracks of the part of crack on the light extraction layer within the field of view corresponding to a surface region of 500 μm square were measured using the optical interferometer for roughness WYKO NT3300 (manufactured by Veecco) and the analysis software Vision 32 (ver.2.303), in the PSI mode under the conditions of 50 magnifications of objective lens and 1 magnification of inside (field of view 90 μm×120 μm), and then evaluated according to the following table.

◯◯: Crack 0 crack

◯: Fine crack having a length of less than 50 μm

1 to 5 cracks

Δ: Fine crack having a length of less than 50 μm

6 or more cracks

x: Large crack having a length of 50 μm or more

1 to 5 cracks, or

fine crack having a length of less than 50 μm 10 or more cracks

xx: Large crack having a length of 50 μm or more 6 or more cracks, or

fine crack having a length of less than 50 μm 20 or more cracks

(2) Uniformity of Light Emission

After carrying out the same bending test to the organic EL element where the transparent electrode, the light-emitting functional layer, the counter electrode and the sealing member were provided on the layered body, the organic EL element was emitted by applying a direct current to each organic EL element at 1000 cd/m² by using the Source measure unit 2400 Type manufactured by KEITHLEY. By using a 50 magnification microscope, the brightness unevenness was observed and evaluated according to the following standard.

◯◯: Emitted completely uniformly

◯: Emitted almost uniformly, and no practical problem

Δ: Observing a slight brightness unevenness partly, but acceptable

x: Observing brightness unevenness allover the surface, and not acceptable

xx: Not emitted partly or all over the surface

(3) Electric Power Efficiency

With respect to the organic EL element, after the same bending test, the front luminance and the angle dependency were measured by using CS-2000 (manufactured by CONIKA MINOLTA SENCING), and measured the electric power efficiency (lm/w) from the driving voltage and the current at a front luminance of 1000 cd/m². The electric power efficiency was evaluated by comparing on the basis of relative value that the electric power efficiency of the organic EL element 101 is assumed to be 100% according to the following standard.

◯◯: 150% or more

◯: 100% or more and less than 150%

Δ: 80% or more and less than 100%

x: 50% or more and less than 80%

xx: Less than 50%

(4) Light Emission Life of Organic EL Element

After subjecting to the same bending test, the organic EL element was allowed to stand in an atmosphere of 85° C. (relative humidity 85%) for 24 hours. Then, the element was emitted continuously by fixing a voltage at which an initial brightness is 5000 cd/m², the time when the brightness is reduced by half was measured as the light emission life.

Next, the ratio respective to the light emission life of the organic EL element 101 after the forced degradation test was calculated, and evaluated according to the following standard.

The ratio of the light emission life is preferably 100% or more preferably 150% or more.

◯◯: 150% or more

◯: 100% or more and less than 150%

Δ: 80% or more and less than 100%

x: 50% or more and less than 80%

xx: Less than 50%

Note that, in the Examples, the bending test (mentioned in Paragraph [0210]) and the tensile test (mentioned in Paragraph [0073]) were carried out in the same way as above.

TABLE 3

| | Transparent | | Light extraction layer | | | | |
|---|---|---|---|---|---|---|---|
| | substrate | | Scattering layer | | | | |
| | | Film | | Island | Distance | Smoothing layer | |
| | | thickness | | diameter | between | | Elongation |
| Sample | Material | (μm) | Structure | (μm) | islands (μm) | Material | (%) |
| 101 | PET | 50 | — | — | — | — | — |
| 102 | | 100 | | | | | |
| 103 | PET | 50 | Flat | — | — | — | — |
| 104 | | | surface | | | Epoxy acrylate | 1 |
| 105 | PET | 50 | Sea-island | 200 | 20 | — | — |
| 106 | | | | 80 | | | |
| 107 | PET | 50 | Flat | — | — | Acrylic resin acrylate | 15 |
| 108 | | 25 | surface | | | Acrylic resin acrylate | 20 |
| 109 | | 10 | | | | Urethane acrylate | 50 |
| 110 | | 10 | | | | Polyurethane acrylate | 150 |
| 111 | PET | 50 | Sea-island | 100 | 10 | Resin material | — |
| 112 | | 50 | | 30 | 2 | | |
| 113 | | 25 | | 70 | 5 | | |
| 114 | | 25 | | 30 | 3 | | |
| 115 | | 10 | | 50 | 2 | | |

| | Evaluation | | | | |
|---|---|---|---|---|---|
| | Layered body | Organic EL element | | | |
| | Bending | Uniformity of | Electric power | Light | |
| Sample | evaluation | light emission | efficiency | emission life | Note |
| 101 | — | ◯ | Standard | Standard | Comparative |
| 102 | — | Δ | X | X | Example |
| 103 | X | XX | XX | XX | Comparative |
| 104 | X | X | XX | XX | Example |
| 105 | X | X | XX | XX | Comparative |
| 106 | ◯ | X | XX | XX | Example |
| 107 | ◯ | ◯◯ | ◯◯ | ◯◯ | Present |
| 108 | ◯ | ◯◯ | ◯◯ | ◯ | invention |
| 109 | ◯ | ◯◯ | ◯◯ | ◯ | |
| 110 | ◯ | ◯◯ | ◯◯ | ◯◯ | |
| 111 | ◯ | ◯ | ◯ | ◯◯ | Present |
| 112 | ◯ | ◯ | ◯ | ◯◯ | invention |
| 113 | ◯ | ◯ | ◯ | ◯◯ | |
| 114 | ◯ | ◯ | ◯ | ◯◯ | |
| 115 | ◯ | ◯ | ◯ | ◯◯ | |

### Evaluation Results of Examples

As is clear from Table 3, it has been confirmed that the layered body of the organic EL elements 107 to 110, namely the layered bodys having the smoothing layer which contains the resin material having an elongation percentage of 10% or more in the tensile test and the inorganic material on the scattering layer have the bending property that no crack is yielded in the bending test, in comparison with the layered bodys of the organic EL elements 101 to 104 which do not have such a specific feature.

Moreover, it has been confirmed that the layered body of the organic EL elements 111 to 115, namely the layered bodys having the scattering layer which contains the sea-island structure in which the light scattering materials are dispersed in the form of island on the transparent substrate have the bending property that no crack is yielded in the bending test, in comparison with the layered bodys of the organic EL elements 101 to 104 which do not have such a specific feature. The organic EL elements 107 to 115 which are provided with the layered body having the bending property that no crack is yielded in the bending test show a high uniformity of light emission and a high electric power efficiency and a long light emission life, and it is clear that the light emission life can be improved without impairing the light extraction efficiency even if bending at an extremely small radius of curvature.

Furthermore, when comparing the organic EL elements 104 and 107 which have the same layer configuration, it has been confirmed that the organic EL element 107, namely the element 107 which has the layered body having the smoothing layer which contains the acrylic resin acrylate having an elongation percentage of 15% in the tensile test has the bending property that no crack is yielded in the bending test. Furthermore, the organic EL element 107 which is provided with such a layered body shows a high uniformity of light emission and a high electric power efficiency and a long light emission life, and the results prove that the configuration in which the smoothing layer which contains the acrylic resin acrylate having an elongation percentage of 10% or more in the tensile test is provided is preferable.

Furthermore, when comparing the organic EL elements 101 and 102 which have the same layer configuration, the organic EL element 101, namely the organic EL element where the transparent substrate having a thickness of 50 μm shows excellent values in the uniformity of light emission, the electric power efficiency and the light emission life, and it has been confirmed that the light emission life can be improved without impairing the light extraction efficiency even if bending at an extremely small radius of curvature.

Furthermore, in comparison of the organic EL elements 107 to 110, and the organic EL elements 111 to 115 which have the same layer configuration, it has been confirmed that, even when the transparent substrate has the thickness of 3 to 50 μm, the good results can be obtained in the uniformity of light emission, the electric power efficiency and the light emission life.

From the above results, it has been confirmed that the organic EL element having the configuration of the present invention can be improved in the uniformity of light emission, the electric power efficiency and also the light emission life. Namely, it has been confirmed that, by using the organic EL element which is provided with the layered body having the bending property that no crack is yielded in the bending test, it is possible to improve the light emission life without impairing the light extraction efficiency even if bending at an extremely small radius of curvature.

Note that the present invention is not limited to the configurations mentioned in the above embodiments, any variation and change can be achieved within the scope of the present invention.

### REFERENCE SIGNS LIST

10, 20: Organic EL element
11: Transparent substrate
1: Light extraction layer
2: Transparent electrode
3: Light-emitting functional layer
5: Counter electrode
1a, 1c: Scattering layer
1b, 1d: Smoothing layer
15, 25: Layered body
H: Emitted light
a: Light scattering particle

1. A light extraction layered body, which is provided on one main surface of a transparent substrate having a thickness of 3 μm or more and 50 μm or less, wherein the light extraction layered body has a bending property of generating no crack when a surface region of 500 μm×500 μm of the light extraction layer is observed with a light diffraction microscope, after a bending test is performed on the layered body under conditions of a radius of curvature of 5 mm, a bending angle of 180 degrees, and bending cycles of ten.

2. An organic electroluminescence element, wherein it has a bending property of generating no brightness unevenness when the brightness unevenness is measured at a time of light emission of 1000 cd/m² with a 50 magnification microscope, after a bending test is performed on an organic electroluminescence element obtained by laminating at least a transparent electrode, a light-emitting functional layer, a counter electrode, and a sealing member on a layered body in which a light extraction layer is provided on one main surface of a transparent substrate having a thickness of 3 μm or more and 50 μm or less under conditions of a radius of curvature of 5 mm, a bending angle of 180 degrees, and bending cycles of ten.

3. The organic electroluminescence element according to claim 2, wherein the layered body has a bending property of generating no crack when a surface region of 500 μm×500 μm of the light extraction layer is observed with a light diffraction microscope, after a bending test is performed on the layered body under conditions of a radius of curvature of 5 mm, a bending angle of 180 degrees, and bending cycles of ten.

4. The organic electroluminescence element according to claim 2, wherein
the light extraction layer is configured by laminating a scattering layer and a smoothing layer in this order on the transparent substrate, and
the smoothing layer contains a resin material having an elongation percentage of 10% or more in a tensile test and an inorganic material.

5. The organic electroluminescence element according to claim 4, wherein the resin material is a resin polymer in which at least one of a urethane acrylate and an acryl resin acrylate is used.

6. The organic electroluminescence element according to claim 3, wherein
the light extraction layer is configured by laminating the scattering layer and the smoothing layer in this order on the transparent substrate, and
the scattering layer has a sea-island structure in which the light scattering materials are dispersed in the form of island on the transparent substrate.

7. The organic electroluminescence element according to claim 6, wherein a diameter of the island in the sea-island structure is 10 μm or more and 100 μm or less.

8. The organic electroluminescence element according to claim 7, wherein a space between adjacent islands is 10 μm or less.

9. A method for manufacturing an organic electroluminescence element by forming a light extraction layer, a transparent electrode, a light-emitting functional layer including a light-emitting layer, a counter electrode on one main surface of a transparent substrate in this order, wherein
the transparent substrate has a thickness of 3 μm or more and 50 μm or less, and
the layered body configured by the transparent substrate and the light extraction layer has a bending property of generating no crack, when a surface region of 500 μm×500 μm of the light extraction layer is observed with a light diffraction microscope after a bending test is performed on the layered body configured by the transparent electrode and the light extraction layer under conditions of a radius of curvature of 5 mm, a bending angle of 180 degrees, and bending cycles of ten.

10. The method for manufacturing an organic electroluminescence element according to claim 9, the method comprising, in the formation of the light extraction layer, forming a scattering layer on the transparent substrate, and then, forming a smoothing layer which contains a resin material and an inorganic material having a refractive index of 2.0 or more on the scattering layer.

11. The method for manufacturing an organic electroluminescence element according to claim 10, wherein
a resin polymer using at least one of a urethane acrylate or an acryl resin acrylate is used as the resin material, and the resin polymer is formed by polymerization through light or heat, after formation of a coating solution containing a monomer or an oligomer on the scattering layer.

12. The method for manufacturing an organic electroluminescence element according to claim 11, wherein a light source used for the photo-polymerization is an excimer UV lamp.

13. The method for manufacturing an organic electroluminescence element according to claim 9, the method comprising, in the formation of the light extraction layer, forming the scattering layer having a sea-island structure by dispersing the light scattering material in a form of island on the transparent substrate, and then, forming a smoothing layer on the scattering layer.
